(19) United States
(12) Patent Application Publication
(10) Pub. No.: US 2026/0076265 A1
(43) Pub. Date: Mar. 12, 2026

(54) COMMUNICATION PROTOCOL USING FREE-SPACE CONNECTIVITY

(71) Applicant: Intel Corporation, Santa Clara, CA (US)

(72) Inventors: Shamsul ABEDIN, Portland, OR (US); Dekang CHEN, Chandler, AZ (US); Stephen MOREIN, San Jose, CA (US); Tina C. TOUPAL, Portland, OR (US); Zhen ZHOU, Chandler, AZ (US)

(21) Appl. No.: 19/389,065

(22) Filed: Nov. 14, 2025

Related U.S. Application Data
(60) Provisional application No. 63/827,026, filed on Jun. 20, 2025.

(51) Int. Cl. H01L 25/16; H01L 23/00; H01L 25/065

(52) U.S. Cl. CPC H10W 90/00; H10W 72/90; H10W 90/20; H10W 90/792

(57) ABSTRACT

A device may include a first die, including: a data transmission interface configured to inductively transmit and receive signals; a processor configured to generate a transmission asynchronous pattern; receive a response pattern via the data transmission interface indicating whether the transmission asynchronous pattern was received by a second die; control a data transfer between the first die and the second die via the data transmission interface based on the response pattern; and a second die, including: a data transmission interface configured to inductively transmit and receive signals; a processor configured to receive the transmission asynchronous pattern; check whether the received transmission asynchronous pattern is correct; generate a response pattern indicating whether the received transmission asynchronous pattern is correct; control a data transfer between the first die and the second die via the data transmission interface based on the check whether the received transmission asynchronous pattern is correct.

### CROSS-REFERENCE TO RELATED APPLICATION(S)

This application claims priority to U.S. provisional application No. 63/827,026 filed on Jun. 20, 2025, the entire contents of which are incorporated herein by reference.

### BACKGROUND

Artificial intelligence (AI) centric applications demand more memory access around computing units such as central processing unit (CPU), graphical processing unit (GPU), and AI accelerator application specific integrated circuit (ASIC) (XPU). Connection interfaces between the individual components of such a system may be formed by a free space interface (e.g. non-contacting interface such as inductive connections, optical connections, or a capacitive connections). However, increased communication demands over such an interface may require employing an additional sideband method—outside the free space interface—for providing additional signaling, which may add additional cost and real estate.

### BRIEF DESCRIPTION OF THE DRAWINGS

In the drawings, like reference characters generally refer to the same parts throughout the different views. The drawings are not necessarily to scale, emphasis instead generally being placed upon illustrating the exemplary principles of the disclosure. In the following description, various exemplary embodiments of the disclosure are described with reference to the following drawings, in which:

FIG. 1 depicts a stacked die and a planer die inductively coupled to each other;

FIG. 2 depicts a first die and a second die inductively coupled to each other in accordance with various aspects;

FIG. 3 depicts a method of initializing a data communication between a first die and a second die in accordance with various aspects;

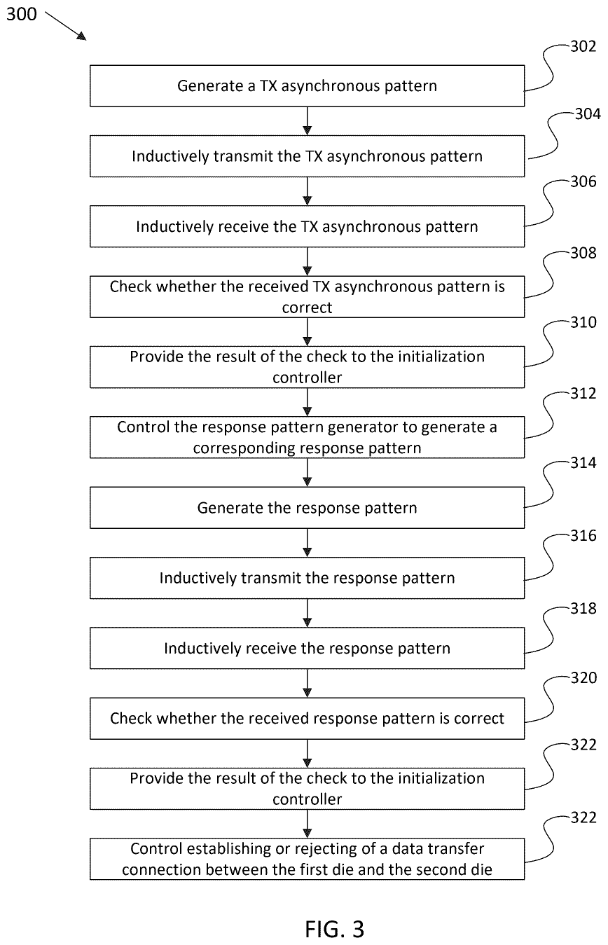

FIG. 4 depicts the first die and the second die of FIG. 1 in debug modes in accordance with various aspects;

FIG. 5 depicts a debug method between a first die and a second die in accordance with various aspects;

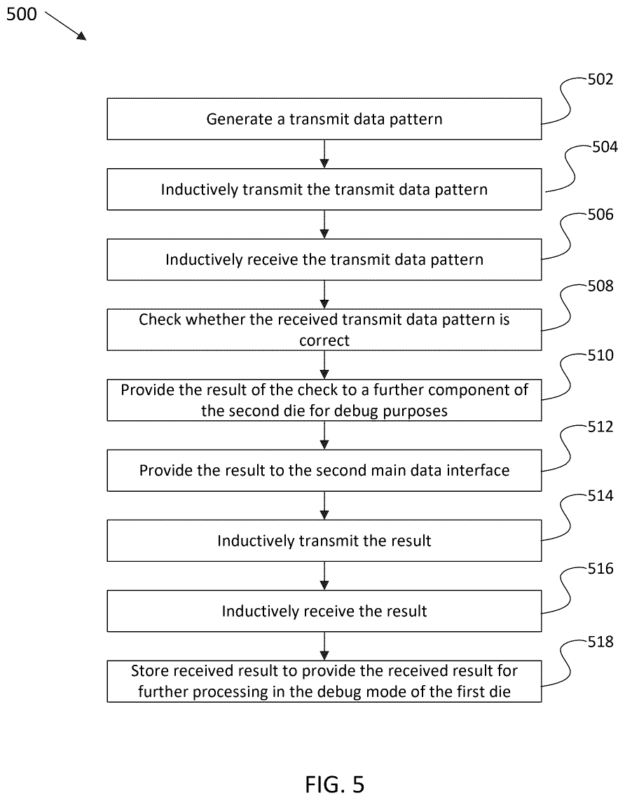

FIG. 6 depicts a first die and a second die inductively coupled to each other in accordance with various aspects;

FIG. 7 shows an example transceiver circuit that may be used for transmitting and receiving pulses via an inductive coupling; and

FIG. 8 shows a device according to various aspects.

### DESCRIPTION

The following detailed description refers to the accompanying drawings that show, by way of illustration, exemplary details and embodiments in which aspects of the present disclosure may be practiced.

The word “exemplary” is used herein to mean “serving as an example, instance, or illustration”. Any embodiment or design described herein as “exemplary” is not necessarily to be construed as preferred or advantageous over other embodiments or designs.

Throughout the drawings, it should be noted that like reference numbers are used to depict the same or similar elements, features, and structures, unless otherwise noted.

The phrase “at least one” and “one or more” may be understood to include a numerical quantity greater than or equal to one (e.g., one, two, three, four, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, [ . . . ], etc.).

The phrases “group (of)”, “set (of)”, “collection (of)”, “series (of)”, “sequence (of)”, “grouping (of)”, etc., in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

As used herein, “memory” is understood as a computer-readable medium (e.g., a non-transitory computer-readable medium) in which data or information may be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, 3D XPoint™, among others, or any combination thereof. Registers, shift registers, processor registers, data buffers, among others, are also embraced herein by the term memory. The term “software” refers to any type of executable instruction, including firmware.

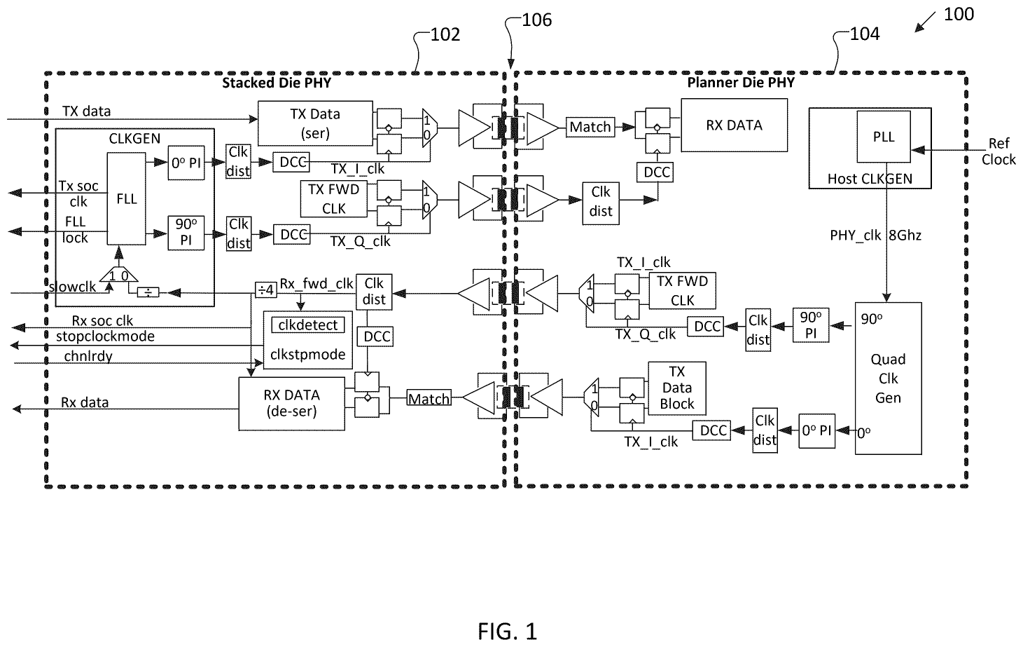

In various aspects, FIG. 1 shows a stacked die 102 with a planer die 104 using free space connectivity such as inductive coupling 106. The unique challenge here is to establish communication between asynchronous dies 102, 104 without additional sideband method other than the free-space connectivity itself, e.g. for initialization.

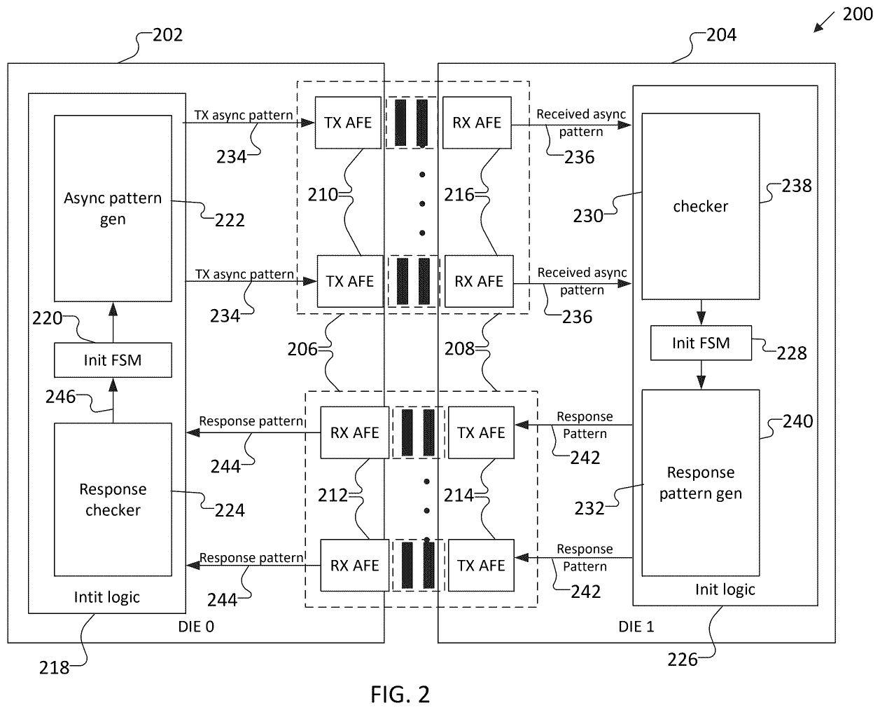

In various aspects, as shown in a circuit 200 in FIG. 2, two dies 202, 204 (e.g. chips), e.g. a first die 202 and a second die 204 communicate with each other asynchronously on independent clocking scheme without clock data recovery, using a main data interface 206, 208 only. By way of example, the first die 202 may include a first main data interface 206 and the second die 204 may include a second main data interface 208. The first main data interface 206 may include one or more transmit (TX) analog front end circuits (AFEs) 210 and one or more receive (RX) analog front end circuits (AFEs) 212. The second main data interface 208 may include one or more transmit (TX) analog front end circuits (AFEs) 214 and one or more receive (RX) analog front end circuits (AFEs) 216. Each TX AFE 210 of the one or more TX AFEs 210 of the first main data interface 206 is inductively coupled with an associated (e.g. exactly one) RX AFE 216 of the second main data interface 208. Furthermore, each TX AFE 214 of the one or more TX AFEs 214 of the second main data interface 208 is inductively coupled with an associated (e.g. exactly one) RX AFE 212 of the first main data interface 206.

Illustratively, initialization of the communication between the first die 202 and the second die 204 may be provided using an asynchronous pattern when using only the main data path (in other words the main data interfaces 206, 208) such as the inductive IOs (e.g. the respective TX AFEs 210, 214 and RX AFEs 212, 216) of the dies 202, 204. It is to be noted that in various aspects, the main data path does not include or provide any indication of (e.g. signals indicating) power-good, reset, clock, or the like.

To implement this, the first die 202 may include a processor 218 (implemented with, e.g., an initialization logic), which may include an initialization controller 220 (e.g. implemented as an initialization finite state machine 220), an asynchronous pattern generator 222 and a response pattern checker 224. The initialization controller 220 is configured to control the initialization process of the first die 202 and e.g. controls the asynchronous pattern generator 222 and receives input signals from the response pattern checker 224. Furthermore, the second die 204 may include an initialization logic 226, which may include an initialization controller 228 (e.g. implemented as an initialization finite state machine 228), an asynchronous pattern checker 230 and a response pattern generator 232. The initialization controller 228 is configured to control the initialization process of the second die 204 and e.g. controls the asynchronous pattern checker 230 and receives input signals from the response pattern generator 232.

The data transmission interface 206 of the first die 202 and/or the processor 218 of the first die 202 may be configured to repeatedly transmit the transmission asynchronous pattern, e.g. during a pre-defined time period. The pre-defined time period may correspond to a boot time in which the circuit 200 performs a device boot sequence.

It is to be noted that the processor 218 of the first die 202 as well as the data transmission interface 206 of the first die 202 are part of the physical (PHY) layer implementation of a radio communication device. Thus, illustratively, the processor 218 of the first die 202 receives data to be transmitted to the second die 204 and a request to initialize a radio connection (also referred to as radio link) to the second die 204 (and thus to start the initialization method, which will be described in more detail below, from a processor of a higher communication layer, e.g. from a processor of a Medium Access Control (MAC) layer. Furthermore, illustratively, the processor 218 of the first die 202 may be configured to provide the result (e.g. a initialization confirmation signal or a of the initialization method to a processor of a higher communication layer, e.g. to a processor of a Medium Access Control (MAC) layer. Furthermore, it is to be noted that the processor 228 of the second die 204 as well as the data transmission interface 208 of the second die 204 are part of the physical (PHY) layer implementation of a radio communication device.

In various aspects, the data transmission interface 206 of the first die 202 may include a first plurality of TX AFEs 210 (e.g. 30 to 40 TX AFEs 210) to provide a first communication channel and a second plurality of TX AFEs 210 (e.g. 30 to 40 TX AFEs 210) to provide a second communication channel. Moreover, the data transmission interface 206 of the first die 202 may include one or more redundancy TX AFEs (not shown), which may be used to replace a damaged TX AFE 210. Correspondingly, the data transmission interface 206 of the first die 202 may include a first plurality of RX AFEs 212 (e.g. 30 to 40 RX AFEs 212) to provide a third communication channel and a second plurality of RX AFEs 212 (e.g. 30 to 40 TX AFEs 212) to provide a fourth communication channel. Moreover, the data transmission interface 206 of the first die 202 may include one or more redundancy RX AFEs (not shown), which may be used to replace a damaged RX AFE 212.

In a similar manner, the data transmission interface 208 of the second die 204 may include a first plurality of RX AFEs 216 (e.g. 30 to 40 RX AFEs 216) to provide the first communication channel and a second plurality of RX AFEs 216 (e.g. 30 to 40 RX AFEs 216) to provide the second communication channel. Moreover, the data transmission interface 208 of the second die 204 may include one or more redundancy RX AFEs (not shown), which may be used to replace a damaged RX AFE 216. Correspondingly, the data transmission interface 208 of the second die 204 may include a first plurality of TX AFEs 214 (e.g. 30 to 40 TX AFEs 214) to provide the third communication channel and a second plurality of TX AFEs 214 (e.g. 30 to 40 TX AFEs 214) to provide the fourth communication channel. Moreover, the data transmission interface 208 of the second die 204 may include one or more redundancy TX AFEs (not shown), which may be used to replace a damaged TX AFE 214.

It is to be noted that although the data transmission interfaces 206, 208 as shown in FIG. 2 are configured to inductively transmit or receive data signals, in alternative implementations, the data transmission interfaces 206, 208 may also be configured to capacitively or optically transmit or receive data signals. Thus, in alternative implementations, the TX AFEs and the associated RX AFEs may be configured to provide a capacitive or optical coupling between each other (i.e., each TX AFE may be configured as a capacitive or optical TX AFE and each RX AFE may be configured as a capacitive or optical RX AFE).

In various aspects, the initialization method 300 may include, in 302, the asynchronous pattern generator 222 generating a TX asynchronous pattern 234 and providing the same to the one or more TX AFEs 210 of the first main data interface 206. The one or more TX AFEs 210 of the first main data interface 206 may, in 304, inductively transmit the TX asynchronous pattern 234 to the associated one or more RX AFEs 216 of the second main data interface 208. The one or more RX AFEs 216 of the second main data interface 208 receive the TX asynchronous pattern 234 in 306. Furthermore, in 308, the asynchronous pattern checker 230 checks whether the received TX asynchronous pattern 236 is correct (i.e. error-free). The asynchronous pattern checker 230 provides the result 238 of the check to the initialization controller 228 of the second main data interface 208 in 310. Depending on the result 238 of the check, the initialization controller 228 of the second main data interface 208 controls (in other words instructs) the response pattern generator 232 (e.g. by a control signal 240) to generate a corresponding response pattern 242 in 312. Then, in 314, the response pattern generator 232 generates the response pattern 242 and provides the same to the one or more TX AFEs 214 of the second main data interface 208. The one or more TX AFEs 214 of the second main data interface 208 may, in 316, inductively transmit the response pattern 242 to the associated one or more RX AFEs 212 of the first main data interface 206. The one or more RX AFEs 212 of the first main data interface 206 receive the response pattern 242 in 318. Furthermore, in 320, the response pattern checker 224 checks whether the received response pattern 244 is correct (i.e. error-free). The response pattern checker 224 provides the result 246 of the check to the initialization controller 220 of the first main data interface 206 in 322. Depending on the result 246 of the check, the initialization controllers 220 228 control establishing or rejecting of a data transfer connection between the first die 202 and the second die 204 via the main data interfaces 206, 208 in 324.

By way of example, if the result 238 of the check to the initialization controller 228 of the second main data interface 208 indicates that the received TX asynchronous pattern 236 is correct and if the result 246 of the check to the initialization controller 220 of the first main data interface 206 indicates that the received response pattern 244 is correct, the data transfer between the first die 202 and the second die 204 via the main data interfaces 206, 208 is started.

However, if the result 238 of the check to the initialization controller 228 of the second main data interface 208 indicates that the received TX asynchronous pattern 236 is not correct or if the result 246 of the check to the initialization controller 220 of the first main data interface 206 indicates that the received response pattern 244 is not correct, the data connection between the first die 202 and the second die 204 may not be established and no data transfer between the first die 202 and the second die 204 is provided. In this case, the initialization controller 220 of the first main data interface 206 and/or the initialization controller 228 of the second main data interface 208 may generate an error signal (not shown in FIG. 2) indicating the failure of the initialization process.

In various aspects, two chips (e.g. the first die 202 and the second die 204) communicate with each other asynchronously on independent clocking scheme without clock data recovery, using the main data interface of the chips only. Without a sideband method to inform its power-on state, a repeated pattern (e.g. the TX asynchronous pattern 234) within a specific time window is used to initiate the communication asynchronously. based on the encoded response, both dies will move forward through the initialization sequence. The TX asynchronous pattern 234 is a unique signal pattern that uniquely identifies the TX asynchronous pattern and distinguishes it from other signaling patterns which may be used for different purposes.

When both dies 202, 204 are configured in debug modes to resolve an issue on the communication link between the first die 202 and the second die 204, one die (e.g. the first die 202) may transmit a predetermined pattern to the other die, which then checks against the known pattern, and vice versa. This mechanism isolates issues on either the transmitting or the receiving die.

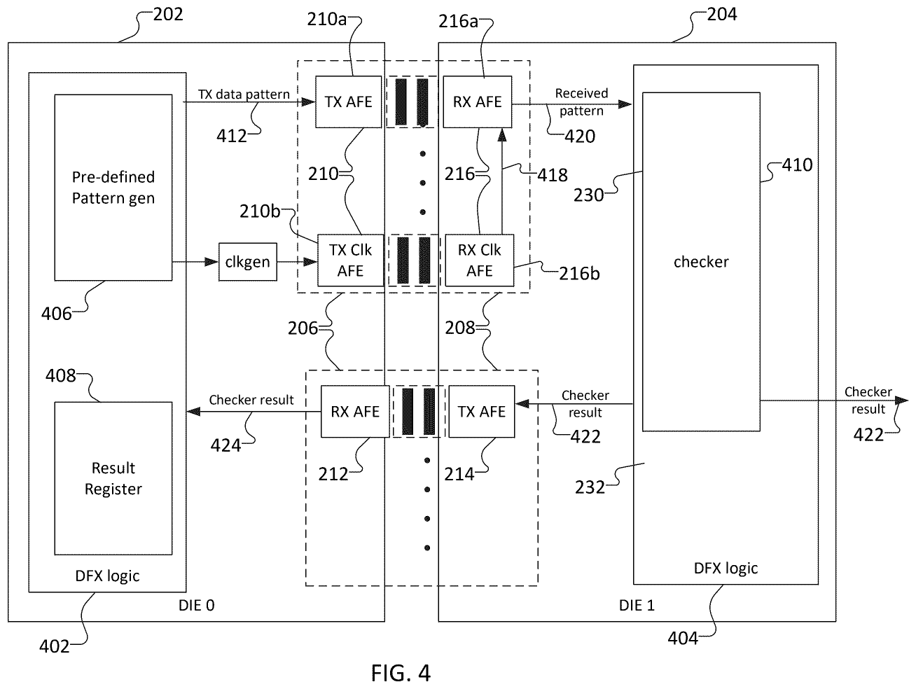

FIG. 4 depicts the first die 202 and the second die 204 of FIG. 1 in debug modes in accordance with various aspects. In various aspects, the first die 202 and the second die 204 may use pre-defined patterns to identify issues in the transmitting die (e.g. the first die 202) or the receiving die (e.g. the second die 204).

To implement the debug mode, the transmitting die (e.g. the first die 202) may include a first logic 402 (e.g. a design for excellence logic (DFX) configured for a debug mode of the first die 202) and the receiving die (e.g. the second die 204) may include a second logic 404 (e.g. a DFX logic configured for a debug mode of the second die 204). The first logic 402 may include a pre-defined pattern generator 406 and a result register 408. The second logic may include a checker (e.g. a checker circuit) 410. The first logic 402 and its components may be implemented or controlled by a processor (e.g. the processor 218). The second logic 404 and its components may be implemented or controlled by a processor (e.g. the processor 218).

The pre-defined pattern generator 406 may be configured to generate a transmit data pattern 412 and to provide the transmit data pattern 412 to the first main data interface 206, e.g. to a first TX AFE 210a of the one or more TX AFEs 210 of the first die 202. Furthermore, the first logic 402 may include a clock generator 414 (e.g. an oscillator circuit, e.g. a local oscillator circuit) configured to generate a clock signal 416 and to provide the clock signal to the first main data interface 206, e.g. to a second TX AFE 210b of the one or more TX AFEs 210 of the first die 202, which may be different from the first TX AFE 210a.

The second main data interface 208 may include a first RX AFE 216a and a second RX AFE 216b. The first RX AFE 216a of the one or more RX AFEs 216 of the second main data interface 208 may be associated with (in other words assigned to) the first TX AFE 210a of the one or more TX AFEs of the first main data interface 206 and may be configured to receive the transmit data pattern 412 from the first TX AFE 210a of the one or more TX AFEs of the first main data interface 206. The second RX AFE 216b of the one or more RX AFEs 216 of the second main data interface 208 may be associated with (in other words assigned to) the second TX AFE 210b of the one or more TX AFEs of the first main data interface 206 and may be configured to receive the clock signal 416 from the second TX AFE 210b of the one or more TX AFEs of the first main data interface 206.

Using a received clock signal 418 and the received transmit data pattern 412, the second main data interface 208 (e.g. the first RX AFE 216a of the one or more RX AFEs 216 of the second main data interface 208) may generate a received data pattern 420 and may provide the same to the second logic 404, e.g. the checker 410.

The checker 410 is configured to check whether the received data pattern 420 is correct or not correct. The checker 410 is further configured to generate a result 422 of the check and may provide the result 422 to the second main data interface 208, e.g. to a TX AFE 214 of the second main data interface 208 to transmit the same to the first die 202. The checker 410 may further be configured to provide the result 422 to another component of the second die 204, e.g. another processor, e.g. a test processor to further process the result in the debug mode of the second die 204. The first main data interface 206, e.g. an RX AFE 212 of the first main data interface 206, may receive the result 422 and may store the received result 424 in the result register 408 to provide the received result 424 for further processing, e.g. analysis, in the debug mode of the first die 202.

Illustratively, a simple check is provided whether the physical radio link is properly established. This may be provided by a link loop-back structure implemented on PHY level.

In various aspects, a debug method 500 may include, in 502, the pre-defined pattern generator 406 generating the transmit data pattern 412 and providing the same to the one or more TX AFEs 210 of the first main data interface 206. The one or more TX AFEs 210 of the first main data interface 206 may, in 504, inductively transmit the transmit data pattern 412 and the clock signal 416 (generated by the clock generator 414 of the first die 202) to the associated one or more RX AFEs 216 of the second main data interface 208. The one or more RX AFEs 216 of the second main data interface 208 receive the transmit data pattern 412 234 in 506.

Furthermore, in 508, the checker 410 checks whether the received data pattern 420 is correct (i.e. error-free). The checker 410, in 510, optionally provides the result 422 of the check to a further component of the second die 204 for debug purposes. The checker 410, in 512, further provides the result 422 of the check to the one or more TX AFEs 214 of the second main data interface 208. The one or more TX AFEs 214 of the second main data interface 208 may, in 514, inductively transmit the result 422 to the associated one or more RX AFEs 212 of the first main data interface 206. The one or more RX AFEs 212 of the first main data interface 206 receive the result in 516. Furthermore, in 518, the method includes storing the received result 424, e.g. in the result register 408, to provide the received result 424 for further processing, e.g. analysis, in the debug mode of the first die 202.

By way of example, if the result 238 of the check to the initialization controller 228 of the second main data interface 208 indicates that the received TX asynchronous pattern 236 is correct and if the result 246 of the check to the initialization controller 220 of the first main data interface 206 indicates that the received response pattern 244 is correct, the data transfer between the first die 202 and the second die 204 via the main data interfaces 206, 208 is started.

However, if the result 238 of the check to the initialization controller 228 of the second main data interface 208 indicates that the received TX asynchronous pattern 236 is not correct or if the result 246 of the check to the initialization controller 220 of the first main data interface 206 indicates that the received response pattern 244 is not correct, the data connection between the first die 202 and the second die 204 may not be established and no data transfer between the first die 202 and the second die 204 is provided. In this case, the initialization controller 220 of the first main data interface 206 and/or the initialization controller 228 of the second main data interface 208 may generate an error signal (not shown in FIG. 2) indicating the failure of the initialization process.

In various aspects, two chips (e.g. the first die 202 and the second die 204) communicate with each other asynchronously on independent clocking scheme without clock data recovery, using the main data interface of the chips only. Without a sideband method to inform its power-on state, a repeated pattern (e.g. the TX asynchronous pattern 234) within a specific time window is used to initiate the communication asynchronously. based on the encoded response, both dies will move forward through the initialization sequence.

It is to be noted, that, since the receiving die may also act as a transmitting die (e.g. the first die 202), the receiving die (e.g. the second die 204) may also include the components of the transmitting die and the transmitting die (e.g. the first die 202) may also include the components of the receiving die (e.g. the second die 204).

In various aspects, the interface between dies may be partially disabled. For example, when some of the input-output (IO) sets (e.g, one set may be the first TX AFE 210a paired with its corresponding first RX AFE 216a) show signs of failure (e.g., a consistent pattern failure or repeated cyclic-redundancy-check (CRC) errors), the failing IO set may be disabled. It should be noted that the disabling of one or more of the IO sets means that the chip operates at a reduced bandwidth. The resilience of the interface may help with debugging and extracting crash dump. In addition, this may also increase the survivability of a chip, with software support.

Partially disabling one or more IO on the interface is possible because the data that is transmitted over the interface is encoded per set. The AFE PHY supports multiple groups of pulsed IO, each with its own encoder and decoder. Therefore, by disabling the encoder/decoder corresponding to a given IO set, the pulsed IO for that particular set is no longer drawing currents, effectively turned off. Any number of IO sets may be turned off, with no impact on the internal data path and controller.

For example, a single die may have x sets of m-bits. Each m-bit set may be decoded into p bits. The raw data bandwidth is x*p bits. If a set needs to be disabled, the total bandwidth is reduced to (x−1)*p bits and the disabled set may be any single set on the interface. If multiple sets need to be disabled, there is no restriction on how the active and inactive sets must be physically arranged, and is thus this design is flexible in terms of physical layout. The raw data is the aggregate of the active sets.

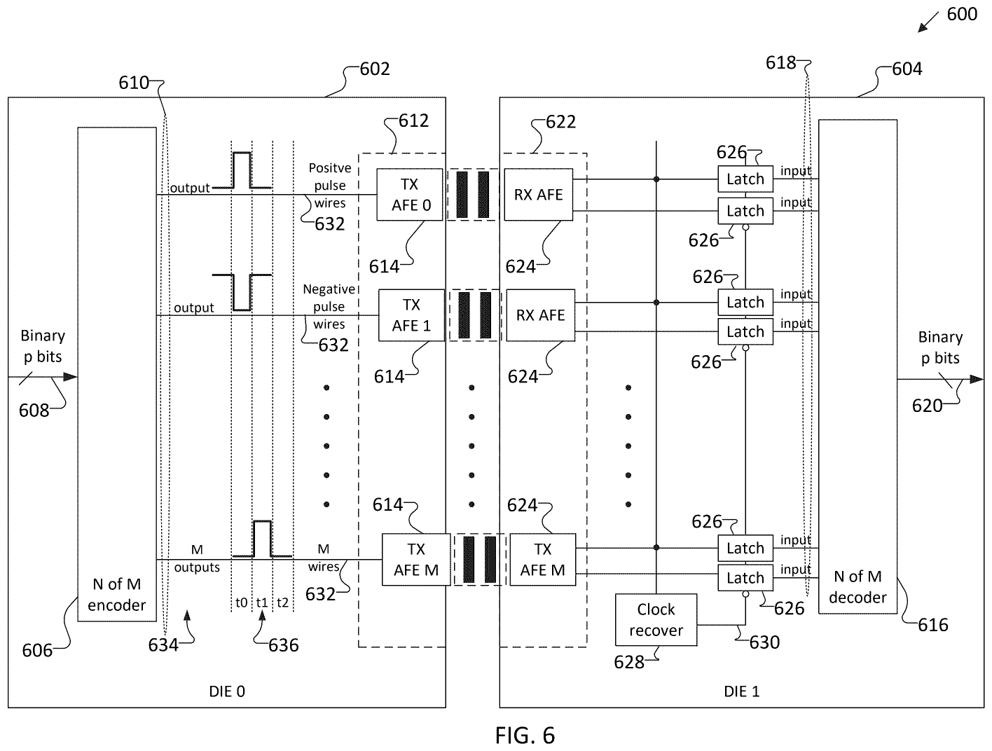

FIG. 6 depicts a structure 600 including a first die 602 and a second die 604 inductively coupled to each other in accordance with various aspects.

In various aspects, pulsed “N of M bit” encoded signals may be used for communicating between two dies in the same package (e.g. a first die 602 (which may be similar to or different from the first die 202) and a second die 604 (which may be similar to or different from the second die 204), in general between any die disposed in the same package). Pulses having three signal levels (e.g. a first (e.g. positive) voltage level pulse (+ve pulse), a second (e.g. negative) voltage level pulse (−ve pulse) and a no transition voltage level state (e.g. implemented by means of providing no current on a respective wire) (e.g. logic “0”) are used.

The first die 602 may include an “N of M” encoder 606 having p inputs 608 to receive p binary input signals (bits) and M outputs 610 (p and M being arbitrary integer numbers). The first die 602 may further include a first main data interface 612. The first main data interface 612 may include one or more (e.g. M) transmit (TX) analog front end circuits (AFEs) 614 and optionally one or more receive (RX) analog front end circuits (AFEs) (not shown in FIG. 6). Each output 610 of the M output 610 may be electrically connected to an associated TX AFE 614 of the M TX AFEs 614.

The second die 604 may include an “N of M” decoder 616 having M inputs 618 to receive M decoder input signals (bits) and p outputs 620. The second die 604 may further include a second main data interface 622. The second main data interface 622 may include one or more receive (RX) analog front end circuits (AFEs) 624 and optionally one or more transmit (TX) analog front end circuits (AFEs) (not shown in FIG. 6). Each TX AFE 614 of the M TX AFEs 614 of the first main data interface 612 is inductively coupled with an associated (e.g. exactly one) RX AFE 624 of the second main data interface 622. The second die 604 may further include a plurality of latches 626 and a clock recovery circuit 628. Each latch 626 is electrically conductively connected to a terminal of an associated (e.g. exactly one) RX AFE 624. The clock recovery circuit 628 is connected to each of the latches 626 to provide them with a clock signal 630. The clock recovery circuit 628 is further connected with each of the RX AFEs 624 to receive a clock recovery signal as a basis for the generation of the clock signal 630.

In various aspects, e.g. a half of the “N” bits are represented by the first (e.g. positive) voltage level pulse (+ve pulse) and the other half of the “N” bits are represented by the second (e.g. negative) voltage level pulse (−ve pulse) that will toggle in one bit time period (t0, t1, t2, . . . ). The same bits will not be toggled in consecutive bit-time periods (t0, t1, t2, . . . ).

FIG. 6 also shows the “N of M” pulse encoding scheme, where in a single bit time period (t0, t1, t2, . . . ) only N number of wires will be pulsed, N/2 of the N numbers will be +ve pulse and N/2 of the M numbers of wires 632 will be −ve pulse. The same bits (in other words wires) will not be pulsed in the respective consecutive bit period. For example, the encoding scheme may implement the “N of M” encoder 606 having M=9, N=2 and p=6. In this example if a bit value “0” is represented by a +ve pulse and a bit value “1” is represented by a −ve pulsed in a first bit time period t0 634, in an immediate consecutive second bit time period t1 636 these two bits (in other words these two wires) will not be pulsed.

It is to be noted that for the encoding scheme above, the equivalent binary number bit symbols is B=Log₂((M−N)*(M−N−1)), where B may be any real number. If B is fractional, then utilizing all the symbol bits may not be as straight forward. Taking, for example, a fractional representation of B to be Q. R where Q is decimal integer and R is an integer representation of the decimal point numbers. In such a case the number of symbols that the binary inputs may represent is between 2^{Q} and 2^{(Q+1)}, so Q+1 bits would be needed to represent binary, but not all symbols in the 2^{(Q+1)} range may be represented by the encoder.

Implementing in hardware a fractional power of two circuits may be complicated, so it is preferable to implement an integer power of two circuit. One way of implementing an integer power of two circuit is to simply use the integer portion of B, which is Q. In this case, however, a number of symbols, 2^{B}−2^{Q}, are lost. Mathematically, the symbol loss may be represented as D=log₂(2^{B}−2^{Q}) bits of symbols. In terms of real-world losses, the number lost symbols translates into a reduced raw data bandwidth.

One way to utilize full symbols with a simpler hardware implementation is to map the binary bits, such that if the most significant bit (MSB) bit (Q+1) is zero then 0 to 2^{Q}−1 symbols may be represented for data payload. If bit (Q+1) is 1, then bit Q to bit D may be set to a fixed value and the D binary bits may be used for command and control.

An example may be provided in the context of a physical link that is capable of transmitting 9 encoded bits every cycle. The 9 bits would yield 42 valid combinations, due to the special circuit restriction. In three cycles, the link would have transmitted 27 bits (9×3) with a total combination of 74,088 (42×42×42). The combined triplet is then decoded to actual data. To determine the maximum amount data that could be sent, the first step is to take the log base 2 of 74,088, which is 16.177. Thus, it would require 17 bits to fully enclose all 74,088 combinations, but not all of the combinations within the full 217 set of combinations may be used, leaving 8,552 unused combinations. For a simpler design approach, the remaining portion of bits (0.177 bits) may be discarded.

Unlike conventional designs, disclosed below is a method for utilizing the remaining combination. Continuing the particular example above, log base 2 of the 8,552 unused combinations yields 13 bits. The remainder is 360, calculated as 8,552−(2¹³)=360. A possible construction of the packet is built upon 17-bit word size. Then, a word may be used to communicate different components with variable sizes. There are three types of components represented by a 17-bit word: a 13-bit header with fixed upper 4 bits, a 16-bit data with fixed MSB, and control words selected from one of the remaining 360 combinations. Table 1 below shows a packet format with variable component sizes.

TABLE 1
Packet Format with Variable Component Sizes

| Component | Decimal Range | Binary Range | Design Requirement |
|---|---|---|---|
| Data | 0-65,535 | 0_0000_0000_0000_0000 to | Bit17 = b′0 |
| | | 0_1111_1111_1111_1111 | |
| Header | 65,536-73,727 | 1_0000_0000_0000_0000 to | Bit[17:14] = b′1000 |
| | | 1_0001_1111_1111_1111 | |
| Control | 73,728-74,087 | 1_0010_0000_0000_0000 to | Bit[17:14] = b′1001 |
| | | 1_0010_0001_0110_1000 | |

Using the example above, a packet with variable component size may use the “lost” bandwidth to transfer header and control words, which are typically required components in any communication links. The header and control words are viewed as overhead that reduces the effective bandwidth for payload data. A benefit of the mechanism disclosed herein may then improve the bandwidth. It should be noted that the mechanism disclosed herein may have a wider application beyond what is shown in the example. In particular, more components may be created by carving out segments of different sizes so as to fully utilize the capability of a physical link.

For example, a group of bit cycles may denote a contiguous set of transmission intervals during which the encoder emits symbols selected from a symbol set that is fixed for that group. Say, then, that the payload data bits to be conveyed in that group have a payload bit length b. For a given group, the encoder may select an integer n as the smallest whole number for which a cardinality of 2ⁿ is at least a minimum cardinality sufficient to uniquely represent all possible values of the payload bit length b; equivalently, the minimum cardinality is 2^{b}. The encoder then defines, for that group, a symbol set of cardinality 2ⁿ and partitions that symbol set into: (i) a payload symbol subset of cardinality 2^{b}; and (ii) an excess subset of cardinality 2ⁿ−2^{b} when 2ⁿ>2^{b}. As should be understood, the term non-payload bits refers to any bits other than the payload bits, including but not limited to header fields, control indicators, error-detection bits, or additional payload bits allocated opportunistically.

For each group of bit cycles, the encoder receives a data stream of bits and identifies the payload portion having payload bit length b. The encoder selects the smallest integer n so that 2ⁿ>2^{b} defines a symbol set of cardinality 2ⁿ for the group, and establishes a one-to-one (bijective) mapping between each possible b-bit payload value and a distinct symbol in the payload symbol subset. Where 2ⁿ exceeds 2^{b}, the encoder additionally establishes a bijection between one or more non-payload bit sequences and distinct symbols in the excess subset, thereby allowing the encoder to carry non-payload information in the same group without reducing the payload mapping's unique decodability. In some embodiments, the encoder orders the symbol set via a fixed enumeration (e.g., indices 0 through 2ⁿ−1, assigns indices 0 through 2^{b}−1 to the payload symbol subset, and assigns indices 2^{b} through 2ⁿ−1 to the excess subset.

When 2ⁿ>2^{b}, the excess cardinality (2ⁿ−2^{b}) may be used to encode non-payload bits of the data stream. Non-payload bits may include, for example: (i) per-group header fields (frame type, sequence number, length, key identifier, redundancy version), (ii) link or flow-control indicators (idle, pause, training, acknowledgment), (iii) error-detection or error-correction check bits computed over payload and/or header, and (iv) additional payload bits to increase the average payload rate over multiple groups. The allocation among these non-payload categories may be static or adaptive. In an adaptive embodiment, the encoder selects, per group, which non-payload fields to embed in the excess subset based on policy or link state, while preserving the same bijective mapping rules.

On the decoder side, given that the symbol set and the payload bit length b are applicable to the group, the decoder determines whether the received symbol is a member of the payload symbol subset or the excess subset. If in the payload subset, the decoder applies the inverse bijection to recover the b-bit payload value. If in the excess subset, the decoder applies the corresponding inverse bijection to recover the mapped non-payload bits (e.g., header fields, control indicators, or additional payload bits). The decoder then reconstructs the output bitstream by placing the recovered payload bits and, if present, recovered non-payload bits into their respective positions for that group.

It should be noted that in certain cases, it may be desirable (e.g., cost effectiveness, depending on the market and application needs in a specific product) to trade off data bandwidth for low power and low latency. In such a case, the range of data bits may be optimized by tapping into the range between 2^{B} and 2^{Q}, which cannot be sufficiently represented by a single term power of 2. However, if this range between 2^{B} and 2^{Q} is ignored, the decoding logic would be much easier to implement at 2^{Q} or any integer number less than Q. In this kind of approach, data may be converted faster because the logical pipeline would be shorter. This trade-off brings the opportunity to reduce power, latency, and cost.

In example of this embodiment, the encoder may reduce bandwidth variability by rounding down the payload mapping to a fixed bit length per group of bit cycles. For a given context in which a group of bit cycles admits a constrained set of symbols of cardinality |T|, the encoder selects a payload bit length b such that 2ⁿ≤|T|, with b=log₂|T|. The encoder then fixes n=b and defines a symbol set of cardinality 2ⁿ=2^{b} for that group.

The encoder bijectively maps each b-bit payload value to a distinct symbol of the symbol set, thereby achieving a deterministic payload rate of b bits per group. For example, if the underlying constrained channel could support an information content of approximately 16.17695 bits per group (as in the earlier example), the encoder sets b=16, and maps exactly 2¹⁶ payload values to selected symbols, and rounds down the achievable payload to 16 bits per group. While rounding down in this manner lowers the bandwidth, it has the benefit of providing a more efficient hardware-based implementation.

It is to be noted that inter-symbol-interference limits the speed at which an interface may operate. This causes a symbol to interfere with a subsequent symbol. In a (normal) binary signaling, where any code may follow any other code, which one may extend N of M to N+2 and M, one may illustratively add the restriction that a given lane cannot be used in two adjacent cycles. Thus, a N=2 of M=7 encoding may transmit 16 bits of data in 3 cycles (detail of why 6*7=42). But inter-symbol-interference limits the frequency to X GHz. With this restriction, one may operate at 2*X GHz, so, by way of example, N=2 of M=7 encodes 0.76 bits per inductive lane (e.g. per encoder output) and at 8 GHz that is 3.6 GBit/lane (e.g. per encoder output). 2+2 of 9 with this restriction may operate at 10 GHz so 0.59 bits/lane and 5.9 GBit.

It is to be noted that the encoder 606 of the first die 202 as well as the TX AFEs 614 (and optionally RX AFEs) of the first die 602 are part of the physical (PHY) layer implementation of a radio communication device or of a memory device. Furthermore, it is to be noted that the decoder 616 of the second die 604 as well as the TX AFEs 624 (and optionally TX AFEs) of the second die 604 are part of the physical (PHY) layer implementation of a radio communication device or of a memory device. It is to be noted that the interface disclosed herein may be used with any type of components to provide a high bandwidth, low latency and high throughput interface between the component, examples of which include a CPUs, GPUs, an AI accelerator ASICs (XPUs), and memories.

It is to be noted that although the TX AFEs 614 and RX AFEs 624 as shown in FIG. 6 are configured to inductively transmit or receive data signals, in alternative implementations, the TX AFEs 614 and RX AFEs 624 may also be configured to capacitively or optically transmit or receive data signals. Thus, in alternative implementations, the TX AFEs and the associated RX AFEs may be configured to provide a capacitive or optical coupling between each other (i.e., each TX AFE may be configured as a capacitive or optical TX AFE and each RX AFE may be configured as a capacitive or optical RX AFE).

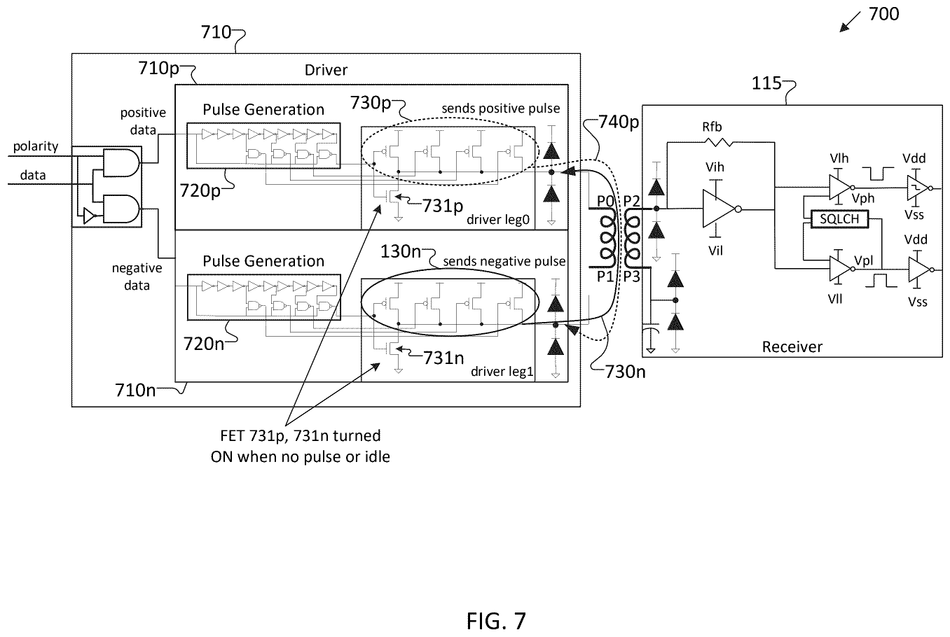

To generate the pulses discussed above, a pulsed driver circuit may be used. The pulse driver circuit may reduce current usage by eliminating the idle current. This may be implemented by parking the two ports of the H-bridge at ground or power, so that no active current flows through the inductor of the H-Bridge. FIG. 7 shows an example transceiver circuit 700 that may be used for transmitting and receiving pulses via the inductive coupling. Circuit 700 has a transmitter 710 with pulse generation circuits 710p (for processing positive pulses), 710n (for processing negative pulses) that generates corresponding pulses based on the polarity of the incoming data. The top pulse generation circuit 710p will turn on the PMOS transistors 730p of the top driver circuit (driver leg0) or turn on the PMOS transistors of the bottom driver circuit (driver leg1). This determines the current pulse direction. When the PMOS transistors 730p are on, the top driver circuit sends a positive pulse 740p to create a positive (+ve) current in the inductor (terminal P0 to terminal P1) and when the PMOS transistors 740p are on, the bottom driver sends a negative pulse 730n to create a negative (−ve) current in the inductor (terminal P1 to terminal P0). When there is no pulse, both to top driver circuit and the bottom driver circuit may switch their corresponding NMOS transistor (731p, 731n respectively) on. Because both sides of the inductor coils terminals P0 and P1 are then at the same voltage, no active current will flow through the inductor. This has the benefit of eliminating large static current that may otherwise flow through the transmitter inductor coil and hence may improve power efficiency for the transmission via inductive coil.

In the pulse generation blocks 720p, 720n, the leading edge of the pulse is generated from the leading edge of the data and all the PMOS transistors 730p, 730n in the corresponding drivers are turned ON at the same time. But for the trailing edge of the pulse, the PMOS transistors are turned off in staggered manner (e.g., due to the delay elements in the pulse generation blocks 720p, 720n) so that the trailing edge has larger slew rate of the current pulse. On the side of the receiver 715, the receiving inductor has the induced voltage at its P2 and P3 terminals based on the equation L*di/dt, where L is the inductance and di/dt is the current slew rate. As a result, two voltage pulses are generated, where one is based on the leading edge and the other is based on the trailing edge. The receiver 715 detects the leading edge so that it may construct the data, irrespective of whether it was a positive pulse or negative pulse. With a lower slew rate (di/dt) of the trailing edge, this induces a lower amplitude of the voltage at the receiving coil and may be suppressed at the receiver 715.

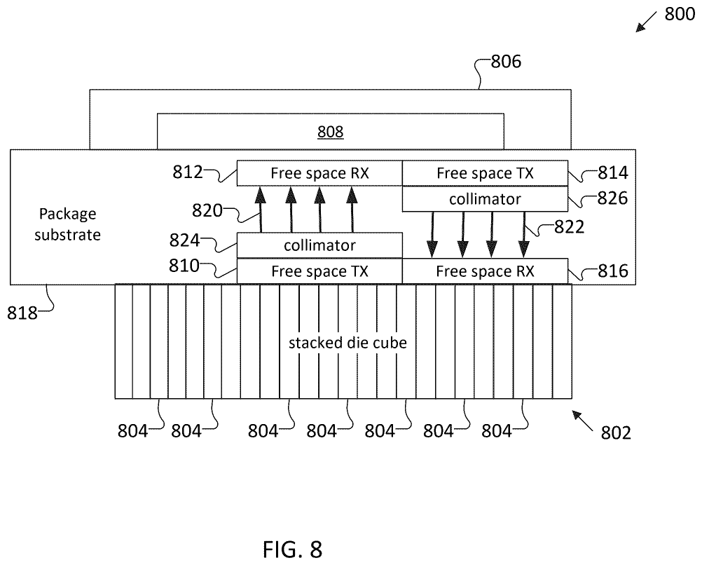

FIG. 8 shows a device 800 in accordance with various aspects.

The device 800 includes a 3D chiplet stack 802. The chiplet stack 802 includes a plurality of (multiple) chiplets 804 with a single base-die (e.g. a bottommost chiplet of the plurality of chiplets 804) which may be connected to a substrate (not shown in FIG. 8). In general, the plurality of chiplets 804 may include an arbitrary number of chiplets 804, e.g. four, five, six, seven, eight, nine, ten, more than ten, up to 15, more than 15, up to 20, more than 20, up to 30, more than 30, up to 50, more than 50, up to 70, more than 70, up to 100, or even more. Each chiplet 804 of the plurality of chiplets 804 may include:
one or more electronic components (e.g. any kind of logic circuit such as e.g. a processor, or any kind of memory circuit);
a plurality of connections electrically connecting the one or more electronic components within the chiplet 804, the plurality of connections formed in one or more metal layers (the plurality of connections may also provide a connection interface to another chiplet 804);
main surfaces (e.g. two main surfaces disposed at opposite sides of the chiplet) and side surfaces (e.g. four side surfaces disposed between the two main surfaces), wherein the main surfaces of adjacent chiplets of the plurality of chiplets 804 face each other.

A memory circuit may include or be a volatile memory circuit, for example a DRAM (Dynamic Random Access Memory) or a non-volatile memory circuit, for example a PROM (Programmable Read Only Memory), an EPROM (Erasable PROM), EEPROM (Electrically Erasable PROM), or a flash memory, e.g., a floating gate memory, a charge trapping memory, an MRAM (Magnetoresistive Random Access Memory) or a PCRAM (Phase Change Random Access Memory), and the like.

The device 800 may further include a carrier 806 comprising a processor 808, e.g. an XPU.

To optically connect the chiplets 804 of the 3D chiplet stack 802 with the processor 808, the device 800 may include a first optical transmitter 810 (e.g. including one or more light emitting diodes or laser diodes), a first optical receiver 812 (e.g. including one or more photo diodes and/or one or more photo transistors), a second optical transmitter 814 (e.g. including one or more light emitting diodes or laser diodes), and a second optical receiver 816 (e.g. including one or more photo diodes and/or one or more photo transistors). The first optical transmitter 810, the first optical receiver 812, the second optical transmitter 814, and the second optical receiver 816 may be provided (e.g. mounted) on one or more package substrates 818. Alternatively, the first optical transmitter 810 and/or the second optical receiver 816 may be provided (e.g. mounted) on the 3D chiplet stack 802. Further, the second optical transmitter 814 and/or the second optical receiver 812 may be provided (e.g. mounted) on the carrier 806.

The first optical transmitter 810 and the first optical receiver 812 may be configured (e.g. positioned relative to each other) to enable an optical (direct or indirect (via one or more optical elements such as one or more mirrors) communication between the same, e.g. via a first optical channel 820 (symbolized in FIG. 8 by first arrows). The first optical channel 820 may be formed by one or more (essentially optically transparent) optical paths for optical signals transmitted by the first optical transmitter 810. Thus, the one or more optical paths extend from the first optical transmitter 810 via the first optical channel 820 to the first optical receiver 812.

The first optical transmitter 810 may be electrically connected to one or more chiplets 804 of the 3D chiplet stack 802 and may be configured to receive electrical signals from the one or more chiplets 804, to generate optical signals using the received electrical signals, wherein the optical signals represent the received electrical signals, and to transmit the optical signals via the first optical channel 820 to the first optical receiver 812.

The first optical receiver 812 may be electrically connected to the processor 808 and may be configured to receive optical signals from the first optical transmitter 810 via the first optical channel 820, to generate electrical signals using the received optical signals, wherein the electrical signals represent the received optical signals, and to provide the electrical signals to the processor 808.

Furthermore, the second optical transmitter 814 and the second optical receiver 816 may be configured (e.g. positioned relative to each other) to enable an optical (direct or indirect (via one or more optical elements such as one or more mirrors) communication between the same, e.g. via a second optical channel 822 (symbolized in FIG. 8 by second arrows). The second optical channel 822 may be formed by one or more (essentially optically transparent) optical paths for optical signals transmitted by the second optical transmitter 814. Thus, the one or more optical paths extend from the second optical transmitter 814 via the second optical channel 822 to the second optical receiver 816.

The (essentially optically transparent) optical paths of the first optical channel 820 and the second optical channel 820 may extend through (for the respective one or more wavelengths of the optical signals transmitted via the optical paths) material of the package substrate 818. The material of the package substrate in the region of the optical paths may be selected to be essentially optically transparent for the optical signals transmitted via the optical paths.

The second optical transmitter 814 may be electrically connected to the processor 808 and may be configured to receive electrical signals from the processor 808, to generate optical signals using the received electrical signals, wherein the optical signals represent the received electrical signals, and to transmit the optical signals via the second optical channel 822 to the second optical receiver 816.

The second optical receiver 816 may be electrically connected to the one or more chiplets 804 of the 3D chiplet stack 802 and may be configured to receive optical signals from the second optical transmitter 814 via the second optical channel 822, to generate electrical signals using the received optical signals, wherein the electrical signals represent the received optical signals, and to provide the electrical signals to the one or more chiplets 804 of the 3D chiplet stack 802.

It is to be noted that the carrier 806 (and thus the processor 808) may in various aspects be include a further 3D chiplet stack (not shown in FIG. 8), which may be similar to the 3D chiplet stack 802.

Thus, using wave propagating through the package substrate 818, two chiplets (or the chiplets 804 and the processor 808) may communicate without direct connections. As shown in the device 800 of FIG. 8, the 3D chiplet stack 802 (also referred to as stacked die cube) with a transmitter (e.g. the first optical transmitter 810) may sends the signals to the processor 808 (e.g. an XPU) through the package substrate 818 in the form of electromagnetic wave, where it uses optical elements 824, 826 (e.g. one or more lenses) for beamforming when an electromagnetic wave is used as the signal carrier. By way of example, a first optical element 824 (e.g. a first optical collimator 824) may be provided (e.g. mounted on the first optical transmitter 810) and a second optical element 826 (e.g. a second optical collimator 826) may be provided (e.g. mounted on the second optical transmitter 814). In case the package substrate 818 is (essentially) optically transparent for certain wavelengths, the carrier signal may be an optical signal. For example, if the package substrate 818 is a glass substrate 818, the optical signal may pass through it. The optical element (e.g. lens) feature may be fabricated in the glass substrate 818 through impurity infusion or through laser writing. The optical element(s) 824, 826 (e.g. the one or more lenses) may be configured as a collimator or a focus element (e.g. either as one or more collimator lenses or as one or more focus lenses). As should be understood, the collimator may be a multi-foci collimator that may cover a wide range of optical devices. If a silicon substrate is used as the package substrate 818, light with a wavelength of wide range may be used as the light source (e.g., at wavelengths of 1000 nm and above). When an organic substrate is used as the package substrate 818, a cavity may be formed in the as the package substrate 818 and e.g. an optically transparent glass may be embedded in the as the package substrate 818 to allow optical signals passing through.

It is to be noted that although the transmitters 814, 814 and receivers 812, 816 as shown in FIG. 8 are configured to optically transmit or receive data signals, in alternative implementations, the transmitters and receivers may also be configured to capacitively or inductively transmit or receive data signals. Thus, in alternative implementations, the transmitters and the associated receivers may be configured to provide a capacitive or inductive coupling between each other (i.e., each transmitter may be configured as a capacitive or inductive transmitter and each receiver may be configured as a capacitive or inductive receiver).

The one or more first optical elements may be configured to be adjustable with respect to the first transmission path (e.g. the first optical path); and/or the one or more second optical elements may be configured to be adjustable with respect to the second transmission path (e.g. the second optical path). A controller (not shown in FIG. 8) may be provided to adjust the one or more first and/or second optical elements.

Moreover, the first transmitter may include a plurality of first transmitter elements and the first receiver may include a plurality of first receiver elements. The device may further include a selector (not shown in FIG. 8) configured to select at least one pair of a first transmitter from the plurality of first transmitters and a first receiver from the plurality of first receivers to provide the first transmission path. Furthermore, the selector may be configured to select at least one pair of a second transmitter from the plurality of second transmitters and a second receiver from the plurality of second receivers to provide the second transmission path. By way of example the selector may determine one or more pairs of transmitters and receivers to provide the best transmission channel (e.g. the best optical transmission path).

Additional aspects of the description will be disclosed by way of example in the following:

Example 1 is device including a first die that includes a data transmission interface configured to transmit and receive signals and a processor configured to generate a transmission asynchronous pattern. The processor is also configured to receive a response pattern via the data transmission interface indicating whether the transmission asynchronous pattern was received by a second die. The processor is also configured to control a data transfer between the first die and the second die via the data transmission interface based on the response pattern. The device also includes a second die that includes a data transmission interface configured to transmit and receive signals and a processor configured to receive the transmission asynchronous pattern. The processor of the second die is also configured to check whether the received transmission asynchronous pattern is correct. The processor of the second die is also configured to generate a response pattern indicating whether the received transmission asynchronous pattern is correct. The processor of the second die is also configured to control a data transfer between the first die and the second die via the data transmission interface based on the check whether the received transmission asynchronous pattern is correct.

Example 2 is the device of Example 1, wherein the data transmission interface of the first die is configured to inductively transmit and receive signals and/or wherein the data transmission interface of the second die is configured to inductively transmit and receive signals.

Example 3 is the device of Example 1, wherein the data transmission interface of the first die is configured to capacitively transmit and receive signals and/or wherein the data transmission interface of the second die is configured to capacitively transmit and receive signals.

Example 4 is the device of Example 1, wherein the data transmission interface of the first die is configured to optically transmit and receive signals and/or wherein the data transmission interface of the second die is configured to optically transmit and receive signals.

Example 5 is the device of any one of Examples 1 to 4, wherein the data transmission interface of the first die includes one or more transmit analog front end circuits configured to transmit signals and/or wherein the data transmission interface of the first die includes one or more receive analog front end circuits configured to receive signals.

Example 6 is the device of any one of Examples 1 to 5, wherein the data transmission interface of the second die includes one or more transmit analog front end circuits configured to transmit signals and/or wherein the data transmission interface of the second die includes one or more receive analog front end circuits configured to receive signals.

Example 7 is the device of any one of Examples 1 to 6, wherein the processor of the first die includes an asynchronous pattern generator, a response pattern checker, and an initialization controller configured to control the asynchronous pattern generator.

Example 8 is the device of Example 7, wherein the processor of the first die includes a finite state machine.

Example 9 is the device of any one of Examples 1 to 8, wherein the processor of the second die includes an asynchronous pattern checker, a response pattern generator, and an initialization controller configured to control the response pattern generator.

Example 10 is the device of Example 9, wherein the processor of the second die includes a finite state machine.

Example 11 is the device of any one of Examples 1 to 10, wherein the data transmission interface of the first die and/or wherein the processor of the first die are/is configured to repeatedly transmit the transmission asynchronous pattern.

Example 12 is the device of Example 11, wherein the data transmission interface of the first die and/or wherein the processor of the first die are/is configured to repeatedly transmit the transmission asynchronous pattern. during a pre-defined time period.

Example 13 is the device of Example 12, wherein the pre-defined time period corresponds to a device boot time in which the device performs a device boot sequence.

Example 14 is the device of any one of Examples 1 to 13, wherein the processor of the first die and the data transmission interface of the first die are part of a physical (PHY) layer circuitry and/or wherein the processor of the second die and the data transmission interface of the second die are part of a physical (PHY) layer circuitry.

Example 15 is a device including a first die that includes a data transmission interface configured to transmit and receive signals and a processor configured to generate a transmit data pattern. The processor is also configured to receive a check result via the data transmission interface indicating whether the transmit data pattern received by a second die was correct. The device also includes a second die that includes a data transmission interface configured to transmit and receive signals and a processor configured to receive the transmit data pattern. The processor of the second die is also configured to check whether the received transmit data pattern is correct. The processor of the second die is also configured to generate a check result indicating whether the received transmit data pattern is correct.

Example 16 is the device of Example 15, wherein the data transmission interface of the first die is configured to inductively transmit and receive signals and/or wherein the data transmission interface of the second die is configured to inductively transmit and receive signals.

Example 17 is the device of Example 15, wherein the data transmission interface of the first die is configured to capacitively transmit and receive signals and/or wherein the data transmission interface of the second die is configured to capacitively transmit and receive signals.

Example 18 is the device of Example 15, wherein the data transmission interface of the first die is configured to optically transmit and receive signals and/or wherein the data transmission interface of the second die is configured to optically transmit and receive signals.

Example 19 is the device of any one of Examples 15 to 18, wherein the processor of the first die is further configured to store the received check result for further processing of a medium access control (MAC) layer component.

Example 20 is the device of Example 19, wherein the processor of the first die is further configured to store the received check result for debugging and to perform a debug process using the stored check result.

Example 21 is the device of any one of Examples 15 to 20, wherein the data transmission interface of the first die includes one or more transmit analog front end circuits configured to transmit signals and/or wherein the data transmission interface of the first die includes one or more receive analog front end circuits configured to receive signals.

Example 22 is the device of Example 15, wherein the data transmission interface of the first die includes a first transmit analog front end circuit configured to transmit the transmit data pattern. The data transmission interface of the first die also includes a second transmit analog front end circuit configured to transmit a clock signal of the first die. The data transmission interface of the first die also includes one or more receive analog front end circuits configured to receive the check result.

Example 23 is the device of Example 22, wherein the data transmission interface of the second die includes a first receive analog front end circuit configured to receive the transmit data pattern. The data transmission interface of the first die also includes a second receive analog front end circuit configured to receive the clock signal of the first die. The data transmission interface of the first die also includes. The data transmission interface of the first die also includes one or more transmit analog front end circuits configured to transmit the check result.

Example 24 is the device of any one of Examples 15 to 23, wherein the processor of the first die includes a pre-defined pattern generator configured to generate the transmit data pattern. The processor of the first die further includes a clock generator configured to generate a clock signal. The processor of the first die further includes a result register configured to store the received result. The processor of the first die further includes a debug controller configured to control the pre-defined pattern generator.

Example 25 is the device of any one of Examples 15 to 24, wherein the processor of the first die is configured as a finite state machine.

Example 26 is the device of any one of Examples 15 to 25, wherein the processor of the second die includes a checker.

Example 27 is the device of any one of Examples 15 to 26, wherein the processor of the second die is configured as a finite state machine.

Example 28 is the device of any one of Examples 15 to 27, wherein the processor of the first die and the data transmission interface of the first die are part of a physical (PHY) layer circuitry and/or wherein the processor of the second die and the data transmission interface of the second die are part of a physical (PHY) layer circuitry.

Example 29 is the device of any one of Examples 15 to 28, wherein the processor is configured to generate the transmit data pattern via a pulsed driver circuit, wherein the pulsed driver circuit includes a pulse generation circuit configured to selectively provide pulses to a driver circuit. The driver circuit includes a set of transistors coupled in series that receives the pulses at an input one of the transistors and outputs the pulses to the data transmission interface. The driver circuit also includes a switching transistor coupled to the input one of the transistors, wherein the pulsed driver circuit is configured to switch on the switching transistor based on no pulses received from the pulse generation circuit.

Example 30 is the device of Example 29, wherein the pulse generation circuit includes a positive pulse generation circuit for processing positive polarities of the transmit data pattern and a negative pulse generation circuit for processing negative polarities of the transmit data pattern. The driver circuit also includes a positive driver circuit coupled to the positive pulse generation circuit and a negative driver circuit coupled to the negative pulse generation circuit. The set of transistors includes a positive set of transistors coupled in series that are coupled to the positive pulse generation circuit at an input one of the positive set of transistors, wherein the positive set of transistors outputs the pulses to the data transmission interface at a first side of an inductor of the transmission interface. The set of transistors further includes a negative set of transistors coupled in series that are coupled to the negative pulse generation circuit at an input one of the negative set of transistors, wherein the negative set of transistors outputs the pulses to the data transmission interface at a second side of the inductor. The switching transistor includes a positive switching transistor coupled to an input one of the positive transistors, wherein the pulsed driver circuit is configured to switch on the positive switching transistor based on no pulses received from the pulse generation circuit. The switching transistor further includes a negative switching transistor coupled to an input one of the negative transistors, wherein the pulsed driver circuit is configured to switch on the negative switching transistor based on no pulses received from the pulse generation circuit.

Example 31 is the device of any one of Examples 29 to 30, wherein the pulse generation circuit includes a set of outputs, each output providing a increasingly delayed version of the pulses to the driver circuit. Each output is coupled to a gate of a corresponding one of the set of transistors, starting with the output with the longest delayed version coupled to the gate of the input one of the set of transistors and continuing with the other outputs in decreasing delay order coupled in series to gates of remaining transistors in the set of transistors.

Example 32 is the device of any one of Examples 29 to 31, wherein the pulse generation circuit is configured to generate a leading edge of each of the pulses based on the leading edge of the data, wherein the pulse generation circuit is configured to increase a slew rate of a trailing edge of the data as compared to the leading edge.

Example 33 is the device of any one of Examples 29 to 32, wherein the pulse generation circuit is configured to turn on the set of transistors at the same time based on a leading edge of the data, wherein the pulse generation circuit is configured to turn off each of transistors in the set of transistors in a staggered manner, wherein the staggered manner includes a decreasing delay in series from the input one of the set of transistors and continuing to a last one of the set of transistors in the series.

Example 34 is the device of any one of Examples 29 to 33, wherein each of the set of transistors is a PMOS transistor.

Example 35 is the device of any one of Examples 29 to 34, wherein the switching transistor is an NMOS transistor.

Example 36 is a device including a first die that includes an encoder including a plurality of encoder outputs and configured to generate bit signals on the encoder outputs of the plurality of encoder outputs. The first die also includes a plurality of transmit analog front end circuits configured to transmit signals, each transmit analog front end circuit coupled to an encoder output of the plurality of encoder outputs, wherein the encoder is configured to in a first time period provided for first bit signals, provide a first bit signal of a first bit signal level representing a first bit value or a first bit signal of a second bit signal level representing a second bit value only on some encoder outputs of the plurality of encoder outputs. The encoder is also configured to, in a second time period, provided for second bit signals, the second time period immediately following the first time period, provide a second bit signal of a first bit signal level representing a first bit value or a second bit signal of a second bit signal level representing a second bit value only on some encoder outputs of the plurality of encoder outputs in which no first bit signals have been provided in the first time period. The device also includes a second die that includes a plurality of receive analog front end circuits configured to receive signals, each receive analog front end circuit inductively coupled with an associated transmit analog front end circuit of the first die. The second die also includes a decoder including a plurality of decoder inputs and a plurality of decoder outputs, wherein each decoder input is coupled to an associated receive analog front end circuit of the plurality of receive analog front end circuits, wherein the decoder is configured to generate bit signals on the decoder outputs based on the signals received on the decoder inputs.

Example 37 is the device of Example 36, wherein the plurality of transmit analog front end circuits are configured to inductively transmit signals and/or wherein the plurality of receive analog front end circuits are configured to inductively receive signals.

Example 38 is the device of Example 36, wherein the plurality of transmit analog front end circuits are configured to capacitively transmit signals and/or wherein the plurality of receive analog front end circuits are configured to capacitively receive signals.

Example 39 is the device of Example 36, wherein the plurality of transmit analog front end circuits are configured to optically transmit signals and/or wherein the plurality of receive analog front end circuits are configured to optically receive signals.

Example 40 is the device of any one of Examples 36 to 39, wherein the second die includes a plurality of latches, each latch being connected between an receive analog front end circuit and an associated decoder input.

Example 41 is the device of any one of Examples 36 to 40, wherein the encoder is configured to, in the first time period, provide the same number of the first bit signals of the first bit signal level and of the first bit signals of the second bit signal level.

Example 42 is the device of any one of Examples 36 to 41, wherein the encoder and the plurality of transmit analog front end circuits of the first die are part of a physical (PHY) layer circuitry and/or wherein the decoder and the plurality of receive analog front end circuits of the second die are part of a physical (PHY) layer circuitry.

Example 43 is the device of any one of Examples 36 to 42, wherein the encoder includes multiple encoders, each of which are associated with one of different transmit sets of the plurality of transmit analog front end circuits, wherein the decoder includes multiple decoders, each of which are associated with one of different receive sets of the plurality of receive analog front end circuits, wherein each corresponding one of the different transmit sets corresponds to a corresponding receive set of the different receive sets, wherein each corresponding one of the different transmit sets and its corresponding one set of the different receive sets.

Example 44 is the device of Example 43, wherein the encoder is configured to disable one transmit set of the different transmit sets and its corresponding receive set based on an indication of error with respect to the one transmit set and its corresponding receive set.

Example 45 is the device of any one of Examples 36 to 44, wherein the indication of error includes a pattern failure or a cyclic redundancy check error.

Example 46 is the device of Example 45, wherein the pattern failure includes a repeating pattern failure over multiple transmissions from the encoder to the decoder.

Example 47 is the device of any one of Examples 45 to 46, wherein the cyclic redundancy check error includes a repeating cyclic redundancy check error over multiple transmissions from the encoder to the decoder.

Example 48 is the device of any one of Examples 36 to 47, wherein the device is configured to reduce a quantity of bit signals on the encoder outputs and a quantity of bit signals on the decoder outputs based on the indication of error with respect to the one transmit set and its corresponding receive set.

Example 49 is the device of any one of Examples 36 to 48, wherein the quantity of bit signals on the encoder outputs and the quantity of bit signals on the decoder outputs correspond to a bandwidth for transmissions through the device.

Example 50 is the device of any one of Examples 36 to 49, wherein the first die is configured to receive a data stream of bits to be encoded onto the first bit signals, wherein payload data bits of the data stream have a payload bit length over a group of bit cycles, wherein the encoder is configured to select an integer n as a smallest whole number for which a cardinality of 2ⁿ is at least a minimum cardinality sufficient to uniquely represent all possible values of the payload bit length over the group of bit cycles. The encoder is further configured to define a symbol set for encoding the data stream over the bit cycles based on the integer n, the symbol set having the cardinality of 2ⁿ. The encoder is further configured to bijectively map the data bits to a distinct symbol of a payload symbol subset of the symbol set that corresponds to the minimum cardinality. The encoder is further configured to bijectively map, if the cardinality of 2ⁿ exceeds the minimum cardinality by an excess cardinality, non-payload bits of the data stream to an excess subset of the symbol subset that is outside of the payload symbol subset and corresponds to the excess cardinality.

Example 51 is the device of any one of Examples 36 to 50, wherein the first die is configured to receive a data stream of bits to be encoded onto the first bit signals, wherein payload data bits of the data stream have a payload bit length over a group of bit cycles, wherein the encoder is configured to select an integer n as a largest integer for which a cardinality of 2ⁿ is less than or equal to a minimum cardinality sufficient to uniquely represent all possible values of the payload bit length over the group of bit cycles. The encoder is further configured to modify the payload bit length for the group to be the integer n. The encoder is further configured to define a symbol set for encoding the data stream over the bit cycles based on the integer n, the symbol set having the cardinality of 2ⁿ. The encoder is further configured to bijectively map the data bits to a distinct symbol of the symbol set.

Example 52 is a device including a plurality of chiplets stacked on top of each other, wherein each chiplet includes one or more electronic components. Each chiplet also includes a plurality of connections electrically connecting the one or more electronic components, the plurality of connections formed in one or more metal layers. Each chiplet also includes main surfaces and side surfaces, wherein the main surfaces of adjacent chiplets of the plurality of chiplets face each other. The device further includes a carrier including a processor. The device further includes a first transmitter electrically coupled to one or more chiplets of the plurality of chiplets. The device further includes a first receiver coupled to the first transmitter and electrically coupled to the processor. The device further includes a second transmitter electrically coupled to the processor. The device further includes a second receiver coupled to the second transmitter and electrically coupled to one or more chiplets of the plurality of chiplets.

Example 53 is the device of Example 52, wherein the first transmitter is a first optical transmitter electrically coupled to one or more chiplets of the plurality of chiplets, wherein the first receiver is a first optical receiver optically coupled to the first optical transmitter and electrically coupled to the processor, wherein the second transmitter is a second optical transmitter electrically coupled to the processor, wherein the second receiver is a second optical receiver optically coupled to the second optical transmitter and electrically coupled to one or more chiplets of the plurality of chiplets.

Example 54 is the device of Example 53, wherein the first transmitter is a first inductive transmitter electrically coupled to one or more chiplets of the plurality of chiplets, wherein the first receiver is a first inductive receiver inductively coupled to the first inductive transmitter and electrically coupled to the processor, wherein the second transmitter is a second inductive transmitter electrically coupled to the processor, wherein the second receiver is a second inductive receiver inductively coupled to the second optical transmitter and electrically coupled to one or more chiplets of the plurality of chiplets.

Example 55 is the device of Example 52, wherein the first transmitter is a first capacitive transmitter electrically coupled to one or more chiplets of the plurality of chiplets, wherein the first receiver is a first capacitive receiver capacitively coupled to the first capacitive transmitter and electrically coupled to the processor, wherein the second transmitter is a second capacitive transmitter electrically coupled to the processor, wherein the second receiver is a second capacitive receiver capacitively coupled to the second capacitive transmitter and electrically coupled to one or more chiplets of the plurality of chiplets.

Example 56 is the device of any one of Examples 52 to 55, the device further including a package substrate positioned between the plurality of chiplets and the carrier, wherein the first receiver is coupled to the first transmitter via the package substrate, and/or wherein the second receiver is coupled to the second transmitter via the package substrate.

Example 57 is the device of any one of Examples 52 to 56, wherein the first receiver is coupled to the first transmitter via a first transmission path that is transparent for signals transmitted by the first transmitter and/or wherein the second receiver is coupled to the second optical transmitter via a second transmission path that is transparent for signals transmitted by the second transmitter.

Example 58 is the device of any one of Examples 56 to 57, wherein the package substrate includes material in a region of the first transmission path and/or the second transmission path that is transparent for signals transmitted by the first transmitter and/or the second transmitter.

Example 59 is the device of any one of Examples 52 to 58, the device further including one or more first optical elements optically coupled to an output of the first optical transmitter; and/or further including one or more second optical elements optically coupled to an output of the second optical transmitter.

Example 60 is the device of Example 59, wherein the one or more first optical elements include one or more first lenses and/or the one or more second optical elements include one or more second lenses.

Example 61 is the device of any one of Examples 59 to 60, wherein the one or more first optical elements are configured as a collimator or as a focus element and/or the one or more second optical elements are configured as a collimator or as a focus element.

Example 62 is the device of any one of Examples 59 to 61, wherein the first receiver is coupled to the first transmitter via a first transmission path that is transparent for signals transmitted by the first transmitter and/or wherein the second receiver is coupled to the second optical transmitter via a second transmission path that is transparent for signals transmitted by the second transmitter. The one or more first optical elements are configured to be adjustable with respect to the first transmission path and/or the one or more second optical elements are configured to be adjustable with respect to the second transmission path.

Example 63 is the device of Example 62, wherein the first transmitter includes a plurality of first transmitter elements, wherein the first receiver includes a plurality of first receiver elements. The device further includes a selector configured to select at least one pair of a first transmitter from the plurality of first transmitters and a first receiver from the plurality of first receivers to provide the first transmission path.

Example 64 is the device of any one of Examples 62 or 63, wherein the second transmitter includes a plurality of second transmitter elements, wherein the second receiver includes a plurality of second receiver elements. The device further including a selector configured to select at least one pair of a second transmitter from the plurality of second transmitters and a second receiver from the plurality of second receivers to provide the second transmission path.

Example 65 is an apparatus including a means for generating a transmission asynchronous pattern. The apparatus also includes a means for receiving a response pattern at a first die via a data transmission interface of the first die indicating whether the transmission asynchronous pattern was received by a second die. The apparatus also includes a means for controlling a data transfer between the first die and the second die via the data transmission interface based on the response pattern. The apparatus also includes a means for receiving at the second die via a data transmission interface of the second die the transmission asynchronous pattern. The apparatus also includes a means for checking whether the received transmission asynchronous pattern is correct. The apparatus also includes a means for generating a response pattern indicating whether the received transmission asynchronous pattern is correct. The apparatus also includes a means for controlling a data transfer between the first die and the second die via the data transmission interface based on the check whether the received transmission asynchronous pattern is correct.

Example 66 is the apparatus of Example 65, the apparatus further including a means for inductively transmitting and receiving signals via the data transmission interface of the first die and/or via the data transmission interface of the second die.

Example 67 is the apparatus of Example 65, the apparatus further including a means for capacitively transmitting and receiving signals via the data transmission interface of the first die and/or via the data transmission interface of the second die.

Example 68 is the apparatus of Example 65, the apparatus further including a means for optically transmitting and receiving signals via the data transmission interface of the first die and/or via the data transmission interface of the second die.

Example 69 is the apparatus of any one of Examples 65 to 68, wherein the data transmission interface of the first die includes one or more transmit analog front end circuits, wherein the apparatus further includes a means for transmitting signals over the one or more transmit analog front end circuits; and/or wherein the data transmission interface of the first die includes one or more transmit analog front end circuits, wherein the apparatus further includes a means for transmitting signals over the one or more receive analog front end circuits.

Example 70 is the apparatus of any one of Examples 65 to 69, wherein the data transmission interface of the second die includes one or more transmit analog front end circuits, wherein the apparatus further includes a means for transmitting signals over the one or more transmit analog front end circuits; and/or wherein the data transmission interface of the second die includes one or more transmit analog front end circuits, wherein the apparatus further includes a means for transmitting signals over the one or more receive analog front end circuits.

Example 71 is the apparatus of any one of Examples 65 to 70, the apparatus further including a means for repeatedly transmitting the transmission asynchronous pattern via the data transmission interface of the first die.

Example 72 is the apparatus of Example 71, wherein the means for repeatedly transmitting the transmission asynchronous pattern includes a means for repeatedly transmitting the transmission asynchronous pattern during a pre-defined time period.

Example 73 is the apparatus of Example 72, wherein the pre-defined time period corresponds to a device boot time in which the device performs a device boot sequence.

Example 74 is an apparatus including a means for generating a transmit data pattern. The apparatus also includes a means for transmitting via a data transmission interface of a first die the transmit data pattern. The apparatus also includes a means for receiving via the data transmission interface of the first die a check result indicating whether the transmit data pattern received by a second die was correct. The apparatus also includes a means for receiving the transmit data pattern via a data transmission interface of the second die. The apparatus also includes a means for checking whether the received transmit data pattern is correct. The apparatus also includes a means for generating a check result indicating whether the received transmit data pattern is correct. The apparatus also includes a means for transmitting the check result to the data transmission interface of the first die.

Example 75 is the apparatus of Example 74, wherein the means for transmitting and the means for receiving via the data transmission interface of the first die includes a means for inductively transmitting and/or wherein the means for transmitting and the means for receiving via the data transmission interface of the second die includes a means for inductively transmitting and receiving.

Example 76 is the apparatus of Example 74, wherein the means for transmitting and the means for receiving via the data transmission interface of the first die includes a means for capacitively transmitting and/or wherein the means for transmitting and the means for receiving via the data transmission interface of the second die includes a means for capacitively transmitting and receiving.

Example 77 is the apparatus of Example 74, wherein the means for transmitting and the means for receiving via the data transmission interface of the first die includes a means for optically transmitting and/or wherein the means for transmitting and the means for receiving via the data transmission interface of the second die includes a means for optically transmitting and receiving.

Example 78 is the apparatus of any one of Examples 74 to 77, the apparatus further including a means for storing the received check result for further processing by a medium access control layer (MAC) component.

Example 79 is the apparatus of Example 78, the apparatus further including a means for storing the received check result for debugging and to perform a debug process using the stored check result.

Example 80 is the apparatus of any one of Examples 74 to 79, wherein the means for transmitting the transmit data pattern via the data transmission interface of the first die includes a means for transmitting via one or more transmit analog front end circuits and/or wherein the means for receiving the check result via the data transmission interface of the first die includes a means for receiving via receive analog front end circuits.

Example 81 is the apparatus of Example 74, wherein the means for transmitting the transmit data pattern includes a means for transmitting the data transmit pattern via a first transmit analog front end circuit of the data transmission interface of the first, wherein the apparatus further includes a means for transmitting via a second transmit analog front end circuit a clock signal of the first die, wherein the means for receiving the check result includes a means for receiving via one or more receive analog front end circuits the check result.

Example 82 is the apparatus of Example 81, wherein the means for receiving the data pattern via the data transmission interface of the second die includes a means for receiving the data pattern via a first receive analog front end circuit of the data transmission interface of the second die, wherein the apparatus further includes a means for receiving via a second receive analog front end circuit of the data transmission interface of the second die the clock signal of the first die, wherein the means for transmitting the check result includes a means for transmitting via one or more transmit analog front end circuits the check result.

Example 83 is the apparatus of any one of Examples 74 to 82, wherein the means for generating the transmit data pattern includes a means for selectively providing pulses to a set of transistors coupled in series that receives the pulses at an input one of the transistors and outputs the pulses to the data transmission interface and a means for switching via a switching transistor the set of transistors on based on no pulses received from the pulse generation circuit.

Example 84 is the apparatus of any one of Examples 82 to 83, the apparatus further including a means for providing an increasingly delayed version of the pulses to the set of transistors so that the transistor connected to an input transistor of the set the transistors receives a longest delay, an output transistor of the set of transistors receives a shortest delay, and remaining transistors in the set of transistors receives the increasingly delated version from the output transistor in series order to the input transistor.

Example 85 is the apparatus of any one of Examples 82 to 84, the apparatus further including a means for generating a leading edge of each of the pulses based on a leading edge of the data. The apparatus also includes a means for increasing a slew rate of a trailing edge of the data as compared to the leading edge.

Example 86 is the apparatus of any one of Examples 82 to 85, the apparatus further including a means for turning on the set of transistors at a same time based on a leading edge of the data. The apparatus also includes a means for turning off each of transistors in the set of transistors in a staggered manner to provide a decreasing delay in series from the input one of the set of transistors and continuing to the output one of the set of transistors in the series.

Example 87 is the apparatus of any one of Examples 82 to 86, wherein each of the set of transistors is a PMOS transistor.

Example 88 is the apparatus of any one of Examples 82 to 87, wherein the switching transistor is an NMOS transistor.

Example 89 is an apparatus including a means for generating bit signals on a plurality of encoder outputs of an encoder, each encoder output outputting to a transmit analog front end circuit of a plurality of transmit analog front end circuits of a first die. The apparatus also includes a means for transmitting signals on the plurality of transmit analog front end circuits, each transmit analog front end circuit coupled to an encoder output of the plurality of encoder outputs. The apparatus also includes a means for providing, in a first time period provided for first bit signals, a first bit signal of a first bit signal level representing a first bit value or a first bit signal of a second bit signal level representing a second bit value only on some encoder outputs of the plurality of encoder outputs. The apparatus also includes a means for providing, in a second time period provided for second bit signals, wherein the second time period immediately follows the first time period, a second bit signal of a first bit signal level representing a first bit value or a second bit signal of a second bit signal level representing a second bit value only on some encoder outputs of the plurality of encoder outputs in which no first bit signals were provided in the first time period. The apparatus also includes a means for receiving signals on a plurality of receive analog front end circuits, each receive analog front end circuit inductively coupled with an associated transmit analog front end circuit of the first die. The apparatus also includes a means for generating bit signals on decoder outputs based on received signals at a plurality of decoder inputs of a decoder, the decoder including a plurality of decoder outputs, wherein each decoder input is coupled to an associated receive analog front end circuit of the plurality of receive analog front end circuits.

Example 90 is the apparatus of Example 89, wherein the means for transmitting the signals includes a means for inductively transmitting the signals and/or wherein the receiving the signals includes inductively receiving the signals.

Example 91 is the apparatus of Example 89, wherein the means for transmitting the signals includes a means for inductively transmitting the signals and/or wherein the receiving the signals includes capacitively receiving the signals.

Example 92 is the apparatus of Example 89, wherein the means for transmitting the signals includes a means for optically transmitting the signals and/or wherein the receiving the signals includes optically receiving the signals.

Example 93 is the apparatus of any one of Examples 89 to 92, wherein the second die includes a plurality of latches, each latch being connected between an receive analog front end circuit and an associated decoder input.

Example 94 is the apparatus of any one of Examples 89 to 93, wherein the means for providing the first bit signals includes a means for providing, in the first time period, a same number of the first bit signals of the first bit signal level and of the first bit signals of the second bit signal level.

Example 95 is the apparatus of any one of Examples 89 to 94, wherein the encoder and the plurality of transmit analog front end circuits of the first die are part of a physical (PHY) layer circuitry and/or wherein the decoder and the plurality of receive analog front end circuits of the second die are part of a physical (PHY) layer circuitry.

Example 96 is the apparatus of any one of Examples 89 to 95, wherein the encoder includes multiple encoders, each of which are associated with one of different transmit sets of the plurality of transmit analog front end circuits, wherein the decoder includes multiple decoders, each of which are associated with one of different receive sets of the plurality of receive analog front end circuits, wherein each corresponding one of the different transmit sets corresponds to a corresponding receive set of the different receive sets, wherein each corresponding one of the different transmit sets and its corresponding one set of the different receive sets.

Example 97 is the apparatus of Example 96, the apparatus further including a means for disabling one transmit set of the different transmit sets and its corresponding receive set based on an indication of error with respect to the one transmit set and its corresponding receive set.

Example 98 is the apparatus of any one of Examples 89 to 97, wherein the indication of error includes a pattern failure or a cyclic redundancy check error.

Example 99 is the apparatus of Example 98, wherein the pattern failure includes a repeating pattern failure over multiple transmissions from the encoder to the decoder.

Example 100 is the apparatus of any one of Examples 98 to 99, wherein the cyclic redundancy check error includes a repeating cyclic redundancy check error over multiple transmissions from the encoder to the decoder.

Example 101 is the apparatus of any one of Examples 89 to 100, the apparatus further including a means for reducing a quantity of bit signals on the encoder outputs and a quantity of bit signals on the decoder outputs based on the indication of error with respect to the one transmit set and its corresponding receive set.

Example 102 is the apparatus of any one of Examples 89 to 101, wherein the quantity of bit signals on the encoder outputs and the quantity of bit signals on the decoder outputs correspond to a bandwidth for transmissions through the device.

Example 103 is the apparatus of any one of Examples 89 to 102, the apparatus further including a means for receiving a data stream of bits to be encoded onto the first bit signals, wherein payload data bits of the data stream have a payload bit length over a group of bit cycles.

The apparatus also includes a means for selecting an integer n as a smallest whole number for which a cardinality of 2ⁿ is at least a minimum cardinality sufficient to uniquely represent all possible values of the payload bit length over the group of bit cycles. The apparatus also includes a means for defining a symbol set for encoding the data stream over the bit cycles based on the integer n, the symbol set having the cardinality of 2ⁿ. The apparatus also includes a means for bijectively mapping the data bits to a distinct symbol of a payload symbol subset of the symbol set that corresponds to the minimum cardinality. The apparatus also includes a means for bijectively mapping, if the cardinality of 2ⁿ exceeds the minimum cardinality by an excess cardinality, non-payload bits of the data stream to an excess subset of the symbol subset that is outside of the payload symbol subset and corresponds to the excess cardinality.

Example 104 is the apparatus of any one of Examples 89 to 103, the apparatus further including a means for receiving a data stream of bits to be encoded onto the first bit signals, wherein payload data bits of the data stream have a payload bit length over a group of bit cycles. The apparatus also includes a means for selecting an integer n as a largest integer for which a cardinality of 2ⁿ is less than or equal to a minimum cardinality sufficient to uniquely represent all possible values of the payload bit length over the group of bit cycles. The apparatus also includes a means for modifying the payload bit length for the group to be the integer n. The apparatus also includes a means for defining a symbol set for encoding the data stream over the bit cycles based on the integer n, the symbol set having the cardinality of 2ⁿ. The apparatus also includes a means for bijectively mapping the data bits to a distinct symbol of the symbol set.

Example 105 is a method including generating a transmission asynchronous pattern. The method also includes receiving a response pattern at a first die via a data transmission interface of the first die indicating whether the transmission asynchronous pattern was received by a second die. The method also includes controlling a data transfer between the first die and the second die via the data transmission interface based on the response pattern. The method also includes receiving at the second die via a data transmission interface of the second die the transmission asynchronous pattern. The method also includes checking whether the received transmission asynchronous pattern is correct. The method also includes generating a response pattern indicating whether the received transmission asynchronous pattern is correct. The method also includes controlling a data transfer between the first die and the second die via the data transmission interface based on the check whether the received transmission asynchronous pattern is correct.

Example 106 is the method of Example 105, the method further including inductively transmitting and receiving signals via the data transmission interface of the first die and/or via the data transmission interface of the second die.

Example 107 is the method of Example 105, the method further including capacitively transmitting and receiving signals via the data transmission interface of the first die and/or via the data transmission interface of the second die.

Example 108 is the method of Example 105, the method further including optically transmitting and receiving signals via the data transmission interface of the first die and/or via the data transmission interface of the second die.

Example 109 is the method of any one of Examples 105 to 108, wherein the data transmission interface of the first die includes one or more transmit analog front end circuits, wherein the method further includes transmitting signals over the one or more transmit analog front end circuits; and/or wherein the data transmission interface of the first die includes one or more transmit analog front end circuits, wherein the method further includes transmitting signals over the one or more receive analog front end circuits.

Example 110 is the method of any one of Examples 105 to 109, wherein the data transmission interface of the second die includes one or more transmit analog front end circuits, wherein the method further includes transmitting signals over the one or more transmit analog front end circuits; and/or wherein the data transmission interface of the second die includes one or more transmit analog front end circuits, wherein the method further includes transmitting signals over the one or more receive analog front end circuits.

Example 111 is the method of any one of Examples 105 to 110, the method further including repeatedly transmitting the transmission asynchronous pattern via the data transmission interface of the first die.

Example 112 is the method of Example 111, wherein the repeatedly transmitting the transmission asynchronous pattern includes repeatedly transmitting the transmission asynchronous pattern during a pre-defined time period.

Example 113 is the method of Example 112, wherein the pre-defined time period corresponds to a device boot time in which the device performs a device boot sequence.

Example 114 is a method including generating a transmit data pattern. The method also includes transmitting via a data transmission interface of a first die the transmit data pattern. The method also includes receiving via the data transmission interface of the first die a check result indicating whether the transmit data pattern received by a second die was correct. The method also includes receiving the transmit data pattern via a data transmission interface of the second die. The method also includes checking whether the received transmit data pattern is correct. The method also includes generating a check result indicating whether the received transmit data pattern is correct. The method also includes transmitting the check result to the data transmission interface of the first die.

Example 115 is the method of Example 114, wherein the transmitting and receiving via the data transmission interface of the first die includes inductively transmitting and/or wherein the transmitting and receiving via the data transmission interface of the second die includes inductively transmitting and receiving.

Example 116 is the method of Example 114, wherein the transmitting and receiving via the data transmission interface of the first die includes capacitively transmitting and/or wherein the transmitting and receiving via the data transmission interface of the second die includes capacitively transmitting and receiving.

Example 117 is the method of Example 114, wherein the transmitting and receiving via the data transmission interface of the first die includes optically transmitting and/or wherein the transmitting and receiving via the data transmission interface of the second die includes optically transmitting and receiving.

Example 118 is the method of any one of Examples 114 to 117, the method further including storing the received check result for further processing by a medium access control layer (MAC) component.

Example 119 is the method of Example 118, the method further including storing the received check result for debugging and to perform a debug process using the stored check result.

Example 120 is the method of any one of Examples 114 to 119, wherein the transmitting the transmit data pattern via the data transmission interface of the first die includes transmitting via one or more transmit analog front end circuits and/or wherein the receiving the check result via the data transmission interface of the first die includes receiving via receive analog front end circuits.

Example 121 is the method of Example 114, wherein the transmitting the transmit data pattern includes transmitting the data transmit pattern via a first transmit analog front end circuit of the data transmission interface of the first, wherein the method further includes transmitting via a second transmit analog front end circuit a clock signal of the first die, wherein the receiving the check result includes receiving via one or more receive analog front end circuits the check result.

Example 122 is the method of Example 121, wherein the receiving the data pattern via the data transmission interface of the second die includes receiving the data pattern via a first receive analog front end circuit of the data transmission interface of the second die, wherein the method further includes receiving via a second receive analog front end circuit of the data transmission interface of the second die the clock signal of the first die, wherein the transmitting the check result includes transmitting via one or more transmit analog front end circuits the check result.

Example 123 is the method of any one of Examples 114 to 122, wherein the generating the transmit data pattern includes selectively providing pulses to a set of transistors coupled in series that receives the pulses at an input one of the transistors and outputs the pulses to the data transmission interface and switching via a switching transistor the set of transistors on based on no pulses received from the pulse generation circuit.

Example 124 is the method of any one of Examples 122 to 123, the method further including providing an increasingly delayed version of the pulses to the set of transistors so that the transistor connected to an input transistor of the set the transistors receives a longest delay, an output transistor of the set of transistors receives a shortest delay, and remaining transistors in the set of transistors receives the increasingly delated version from the output transistor in series order to the input transistor.

Example 125 is the method of any one of Examples 122 to 124, the method further including generating a leading edge of each of the pulses based on a leading edge of the data. The method also includes increasing a slew rate of a trailing edge of the data as compared to the leading edge.

Example 126 is the method of any one of Examples 122 to 125, the method further including turning on the set of transistors at a same time based on a leading edge of the data. The method also includes turning off each of transistors in the set of transistors in a staggered manner to provide a decreasing delay in series from the input one of the set of transistors and continuing to the output one of the set of transistors in the series.

Example 127 is the method of any one of Examples 122 to 126, wherein each of the set of transistors is a PMOS transistor.

Example 128 is the method of any one of Examples 122 to 127, wherein the switching transistor is an NMOS transistor.

Example 129 is a method including generating bit signals on a plurality of encoder outputs of an encoder, each encoder output outputting to a transmit analog front end circuit of a plurality of transmit analog front end circuits of a first die. The method also includes transmitting signals on the plurality of transmit analog front end circuits, each transmit analog front end circuit coupled to an encoder output of the plurality of encoder outputs. The method also includes providing, in a first time period provided for first bit signals, a first bit signal of a first bit signal level representing a first bit value or a first bit signal of a second bit signal level representing a second bit value only on some encoder outputs of the plurality of encoder outputs. The method also includes providing, in a second time period provided for second bit signals, wherein the second time period immediately follows the first time period, a second bit signal of a first bit signal level representing a first bit value or a second bit signal of a second bit signal level representing a second bit value only on some encoder outputs of the plurality of encoder outputs in which no first bit signals were provided in the first time period. The method also includes receiving signals on a plurality of receive analog front end circuits, each receive analog front end circuit inductively coupled with an associated transmit analog front end circuit of the first die. The method also includes generating bit signals on decoder outputs based on received signals at a plurality of decoder inputs of a decoder, the decoder including a plurality of decoder outputs, wherein each decoder input is coupled to an associated receive analog front end circuit of the plurality of receive analog front end circuits.

Example 130 is the method of Example 129, wherein the transmitting the signals includes inductively transmitting the signals and/or wherein the receiving the signals includes inductively receiving the signals.

Example 131 is the method of Example 129, wherein the transmitting the signals includes inductively transmitting the signals and/or wherein the receiving the signals includes capacitively receiving the signals.

Example 132 is the method of Example 129, wherein the transmitting the signals includes optically transmitting the signals and/or wherein the receiving the signals includes optically receiving the signals.

Example 133 is the method of any one of Examples 129 to 132, wherein the second die includes a plurality of latches, each latch being connected between an receive analog front end circuit and an associated decoder input.

Example 134 is the method of any one of Examples 129 to 133, wherein the providing the first bit signals includes providing, in the first time period, a same number of the first bit signals of the first bit signal level and of the first bit signals of the second bit signal level.

Example 135 is the method of any one of Examples 129 to 134, wherein the encoder and the plurality of transmit analog front end circuits of the first die are part of a physical (PHY) layer circuitry and/or wherein the decoder and the plurality of receive analog front end circuits of the second die are part of a physical (PHY) layer circuitry.

Example 136 is the method of any one of Examples 129 to 135, wherein the encoder includes multiple encoders, each of which are associated with one of different transmit sets of the plurality of transmit analog front end circuits, wherein the decoder includes multiple decoders, each of which are associated with one of different receive sets of the plurality of receive analog front end circuits, wherein each corresponding one of the different transmit sets corresponds to a corresponding receive set of the different receive sets, wherein each corresponding one of the different transmit sets and its corresponding one set of the different receive sets.

Example 137 is the method of Example 136, the method further including disabling one transmit set of the different transmit sets and its corresponding receive set based on an indication of error with respect to the one transmit set and its corresponding receive set.

Example 138 is the method of any one of Examples 129 to 137, wherein the indication of error includes a pattern failure or a cyclic redundancy check error.

Example 139 is the method of Example 138, wherein the pattern failure includes a repeating pattern failure over multiple transmissions from the encoder to the decoder.

Example 140 is the method of any one of Examples 138 to 139, wherein the cyclic redundancy check error includes a repeating cyclic redundancy check error over multiple transmissions from the encoder to the decoder.

Example 141 is the method of any one of Examples 129 to 140, the method further including reducing a quantity of bit signals on the encoder outputs and a quantity of bit signals on the decoder outputs based on the indication of error with respect to the one transmit set and its corresponding receive set.

Example 142 is the method of any one of Examples 129 to 141, wherein the quantity of bit signals on the encoder outputs and the quantity of bit signals on the decoder outputs correspond to a bandwidth for transmissions through the device.

Example 143 is the method of any one of Examples 129 to 142, the method further including receiving a data stream of bits to be encoded onto the first bit signals, wherein payload data bits of the data stream have a payload bit length over a group of bit cycles. The method also includes selecting an integer n as a smallest whole number for which a cardinality of 2ⁿ is at least a minimum cardinality sufficient to uniquely represent all possible values of the payload bit length over the group of bit cycles. The method also includes defining a symbol set for encoding the data stream over the bit cycles based on the integer n, the symbol set having the cardinality of 2ⁿ. The method also includes bijectively mapping the data bits to a distinct symbol of a payload symbol subset of the symbol set that corresponds to the minimum cardinality. The method also includes bijectively mapping, if the cardinality of 2ⁿ exceeds the minimum cardinality by an excess cardinality, non-payload bits of the data stream to an excess subset of the symbol subset that is outside of the payload symbol subset and corresponds to the excess cardinality.

Example 144 is the method of any one of Examples 129 to 143, the method further including receiving a data stream of bits to be encoded onto the first bit signals, wherein payload data bits of the data stream have a payload bit length over a group of bit cycles. The method also includes selecting an integer n as a largest integer for which a cardinality of 2ⁿ is less than or equal to a minimum cardinality sufficient to uniquely represent all possible values of the payload bit length over the group of bit cycles. The method also includes modifying the payload bit length for the group to be the integer n. The method also includes defining a symbol set for encoding the data stream over the bit cycles based on the integer n, the symbol set having the cardinality of 2ⁿ. The method also includes bijectively mapping the data bits to a distinct symbol of the symbol set.

While the above descriptions and connected figures may depict components as separate elements, skilled persons will appreciate the various possibilities to combine or integrate discrete elements into a single element. Such may include combining two or more circuits for form a single circuit, mounting two or more circuits onto a common chip or chassis to form an integrated element, executing discrete software components on a common processor core, etc. Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

Claimed is:

1. A device comprising:
a plurality of chiplets stacked on top of each other, wherein each chiplet comprises:
one or more electronic components;
a plurality of connections electrically connecting the one or more electronic components, the plurality of connections formed in one or more metal layers; and
main surfaces and side surfaces, wherein the main surfaces of adjacent chiplets of the plurality of chiplets face each other;
a carrier comprising a processor;
a first transmitter electrically coupled to one or more chiplets of the plurality of chiplets;
a first receiver coupled to the first transmitter and electrically coupled to the processor;
a second transmitter electrically coupled to the processor; and
a second receiver coupled to the second transmitter and electrically coupled to one or more chiplets of the plurality of chiplets.

2. The device of claim 1,
wherein the first transmitter is a first optical transmitter electrically coupled to one or more chiplets of the plurality of chiplets,
wherein the first receiver is a first optical receiver optically coupled to the first optical transmitter and electrically coupled to the processor,
wherein the second transmitter is a second optical transmitter electrically coupled to the processor,
wherein the second receiver is a second optical receiver optically coupled to the second optical transmitter and electrically coupled to one or more chiplets of the plurality of chiplets.

3. The device of claim 2,
wherein the first transmitter is a first inductive transmitter electrically coupled to one or more chiplets of the plurality of chiplets,
wherein the first receiver is a first inductive receiver inductively coupled to the first inductive transmitter and electrically coupled to the processor,
wherein the second transmitter is a second inductive transmitter electrically coupled to the processor,
wherein the second receiver is a second inductive receiver inductively coupled to the second optical transmitter and electrically coupled to one or more chiplets of the plurality of chiplets.

4. The device of claim 1,
wherein the first transmitter is a first capacitive transmitter electrically coupled to one or more chiplets of the plurality of chiplets,
wherein the first receiver is a first capacitive receiver capacitively coupled to the first capacitive transmitter and electrically coupled to the processor,
wherein the second transmitter is a second capacitive transmitter electrically coupled to the processor,
wherein the second receiver is a second capacitive receiver capacitively coupled to the second capacitive transmitter and electrically coupled to one or more chiplets of the plurality of chiplets.

5. The device of claim 1, the device further comprising a package substrate positioned between the plurality of chiplets and the carrier, wherein the first receiver is coupled to the first transmitter via the package substrate, and/or wherein the second receiver is coupled to the second transmitter via the package substrate.

6. The device of claim 1, wherein the first receiver is coupled to the first transmitter via a first transmission path that is transparent for signals transmitted by the first transmitter and/or wherein the second receiver is coupled to the second transmitter via a second transmission path that is transparent for signals transmitted by the second transmitter.

7. The device of claim 6, the device further comprising a package substrate positioned between the plurality of chiplets and the carrier, wherein the package substrate comprises material in a region of the first transmission path and/or the second transmission path that is transparent for signals transmitted by the first transmitter and/or the second transmitter.

8. The device of claim 1, the device further comprising one or more first optical elements optically coupled to an output of the first transmitter and/or wherein one or more second optical elements optically coupled to an output of the second transmitter.

9. The device of claim 8, wherein the one or more first optical elements comprise one or more first lenses and/or wherein one or more second optical elements comprise one or more second lenses.

10. The device of claim 8, wherein the one or more first optical elements are configured as a collimator or as a focus element and/or wherein one or more second optical elements are configured as a collimator or as a focus element.

11. The device of claim 8, wherein the first receiver is coupled to the first transmitter via a first transmission path that is transparent for signals transmitted by the first transmitter and/or wherein the second receiver is coupled to the second transmitter via a second transmission path that is transparent for signals transmitted by the second transmitter, and wherein the one or more first optical elements are configured to be adjustable with respect to the first transmission path and/or wherein the one or more second optical elements are configured to be adjustable with respect to the second transmission path.

12. The device of claim 11,
wherein the first transmitter comprises a plurality of first transmitter elements,
wherein the first receiver comprises a plurality of first receiver elements,
the device further comprising a selector configured to select at least one pair of a first transmitter from the plurality of first transmitters and a first receiver from the plurality of first receivers to provide the first transmission path.

13. The device of claim 11,
wherein the second transmitter comprises a plurality of second transmitter elements,
wherein the second receiver comprises a plurality of second receiver elements,
the device further comprising a selector configured to select at least one pair of a second transmitter from the plurality of second transmitters and a second receiver from the plurality of second receivers to provide the second transmission path.

14. A device comprising:
a first die and a second die, the first die comprising a data transmission interface configured to transmit and receive signals and a processor configured to:
generate a transmission asynchronous pattern;
receive a response pattern via the data transmission interface indicating whether the transmission asynchronous pattern was received by a second die; and
control a data transfer between the first die and the second die via the data transmission interface based on the response pattern, the second die comprising:
a data transmission interface configured to transmit and receive signals and a processor configured to:
receive the transmission asynchronous pattern;
check whether the received transmission asynchronous pattern is correct;
generate a response pattern indicating whether the received transmission asynchronous pattern is correct; and
control a data transfer between the first die and the second die via the data transmission interface based on the check whether the received transmission asynchronous pattern is correct.

15. The device of claim 14, wherein the data transmission interface of the first die and/or of the second die is configured to inductively, capacitively, or optically transmit and receive signals and/or wherein the data transmission interface of the second die is configured to inductively transmit and receive signals.

16. The device of claim 14, wherein the data transmission interface of the first die comprises one or more transmit analog front end circuits configured to transmit signals and/or wherein the data transmission interface of the first die comprises one or more receive analog front end circuits configured to receive signals.

17. The device of claim 14, wherein the data transmission interface of the second die comprises one or more transmit analog front end circuits configured to transmit signals and/or wherein the data transmission interface of the second die comprises one or more receive analog front end circuits configured to receive signals.

18. The device of claim 14, wherein the processor of the first die comprises:
an asynchronous pattern generator;
a response pattern checker; and
an initialization controller configured to control the asynchronous pattern generator.

19. A device comprising:
a first die and a second die, the first die comprising:
an encoder comprising a plurality of encoder outputs and configured to generate bit signals on the encoder outputs of the plurality of encoder outputs;
a plurality of transmit analog front end circuits configured to transmit signals, each transmit analog front end circuit coupled to an encoder output of the plurality of encoder outputs, wherein the encoder is configured to:
in a first time period provided for first bit signals, provide a first bit signal of a first bit signal level representing a first bit value or a first bit signal of a second bit signal level representing a second bit value only on some encoder outputs of the plurality of encoder outputs; and
in a second time period provided for second bit signals, the second time period immediately following the first time period, provide a second bit signal of a first bit signal level representing a first bit value or a second bit signal of a second bit signal level representing a second bit value only on some encoder outputs of the plurality of encoder outputs in which no first bit signals have been provided in the first time period,
wherein the second die comprises:
a plurality of receive analog front end circuits configured to receive signals, each receive analog front end circuit inductively coupled with an associated transmit analog front end circuit of the first die; and
a decoder comprising a plurality of decoder inputs and a plurality of decoder outputs, wherein each decoder input is coupled to an associated receive analog front end circuit of the plurality of receive analog front end circuits, wherein the decoder is configured to generate bit signals on the decoder outputs based on the signals received on the decoder inputs.

20. The device of claim 19, wherein the encoder comprises multiple encoders, each of which are associated with one of different transmit sets of the plurality of transmit analog front end circuits, wherein the decoder comprises multiple decoders, each of which are associated with one of different receive sets of the plurality of receive analog front end circuits, wherein each corresponding one of the different transmit sets corresponds to a corresponding receive set of the different receive sets, wherein each corresponding one of the different transmit sets and its corresponding one set of the different receive sets.
